(19) United States
(12) Patent Application Publication
(10) Pub. No.: US 2021/0364149 A1
(43) Pub. Date: Nov. 25, 2021

(54) LIGHT-REFLECTIVE-TYPE PROFILE SURFACE FOR LIGHT DIFFUSION AND CONCENTRATION, AND SURFACE-EMITTING LIGHTING AND LIGHT CONCENTRATION APPARATUS USING SAME

(71) Applicant: LINFINITY INC., Seoul (KR)

(72) Inventor: Young-Mee KANG, Seoul (KR)

(21) Appl. No.: 16/968,162

(22) PCT Filed: Nov. 28, 2018
(86) PCT No.: PCT/KR2018/014756

§ 371 Date: Aug. 7, 2020

(30) Foreign Application Priority Data
Feb. 8, 2018 (KR) 10-2018-0015562
Mar. 22, 2018 (KR) 10-2018-0033216

(51) Int. Cl. F21V 7/28; G02B 5/02; F21V 7/09

(52) U.S. Cl. CPC F21V 7/28; F21V 7/09; G02B 5/0284

(57) ABSTRACT

The present invention provides a reflective member (10) for emitting a diffused second reflected light (63) in a second direction different from a first direction, if an incident light (61) is incident in the first direction, and for emitting a concentrated second reflected light (73) in the first direction, if an incident light (71) is incident in the second direction, the reflective member comprising: a reflective profile surface (13) for reflecting the incident light; and a first reflective surface (14) and a second reflective surface (15) provided in an alternating manner on the reflective profile surface (13) along the lengthwise direction thereof. The reflective member (10) may further comprise a film member (11) having a first surface having the reflective profile surface (13), and a second surface facing the first surface.

### FIELD OF THE INVENTION

The present invention relates to a planar illuminating and light concentrating apparatus which has a light reflective surface configured to diffuse or concentrate light according to the direction of incident light.

### BACKGROUND OF THE INVENTION

In general, a light emitting diode has better efficiency than a conventional light bulb, and it is widely used in various fields. Light emitting diodes are widely used in industrial fields such as semiconductor exposure equipment, as well as indoor lighting for people in a living area.

However, light-emitting diodes are more like intensive point lighting. Since such point lighting has a very high luminance, it is inappropriate to use it as direct lighting, and if a person looks directly at it, the optic nerve may be damaged. Accordingly, a planar lighting structure that indirectly magnifies light from point-emitting LEDs is widely used.

Most of these types of planar lighting use a light guide plate and a prism sheet to magnify the light emitting area and increase the luminance by directing the light direction forward.

Additionally in order to realize planar illumination, a method of uniformly distributing and mounting light emitting diodes in an area corresponding to a planar light is also used.

However, since the optical member or the prism sheet, such as a light guide plate, has a high cost, the cost of the illumination is also increased. When the light emitting diode is disposed corresponding to the light emitting area, the more the light emitting diode needs to be used as the planar illuminating area increases.

Due to the problem above, a structure in which light emitting diodes are installed at edges and emitted to the side has been used for realizing flat lighting. But the use of the light guide plate and the prism sheet is mandatory, the cost of lighting apparatus is inevitably increased.

The related art is disclosed in Korean Patent Publication No. 1829098, No. 1193503, and Korean Registered Utility Publication No. 483741.

On the other hand, as the demand for efficient use of energy increases, research on power generation facilities using sunlight is actively being conducted. Initially, research on the efficiency of solar cells that convert sunlight into electricity has been actively conducted.

However, even if the electric energy conversion efficiency of the cell increases, the meaning that the solar cell conversion efficiency is high is faded when the sunlight itself is weak. In addition, since the price of a cell is proportional to the area, it is more efficient to produce more electrical energy using a cell with a smaller area.

Accordingly, various photovoltaic power generation modules are being developed which reduce the area of a solar cell by concentrating sunlight to the solar cells. For example, a refraction method through an optical lens or a reflection method through a reflective dish mirror.

However, all of these devices require a certain distance between a light concentrating device that causes light reflection or refraction and a solar cell to which the concentrated light is irradiated, which greatly increases the size of the overall solar power module. Therefore, due to the limitation of the space itself in which the photovoltaic module can be installed, the condition for using those devices is very limited.

In addition, since the conventional devices are provided with a plurality of focal points, there is a problem that a plurality of small solar cells must be separately installed, and the plurality of solar cells must be individually cooled. And if the incident angle is changed, the concentrated sunlight leaves the irradiation surface of the solar cell.

Since the photovoltaic module has a large area, the phenomenon of being bent in the wind occurs, which leads to a problem that the efficiency of a conventional photovoltaic power generation module is very sensitive to wind.

The related art includes Korean Patent Publication Nos. 1492203, 1629603, 1765932, and 1770164.

### SUMMARY OF THE INVENTION

### Technical Subject

The present invention has been made to solve the above-mentioned problems, and a purpose thereof is providing a light reflective surface structure having the same pattern, wherein light may be concentrated or magnified according to an incident direction of light.

In addition, the present invention has been made to solve the above-mentioned problems, and a purpose of the present invention is to provide a lighting device which uses the light reflective surface structure, minimizes the number of installation of a light emitting diode, and can sufficiently realize planar illumination even if the light guide plate and the prism sheet are omitted.

In addition, an purpose of the present invention is to provide a lighting device that is simple and compact in manufacturing, and can greatly reduce cost.

In addition, an object of the present invention is to provide a lighting device that can be used in an optimal lighting state by flexibly deforming the planar illuminating surface.

In addition, another object of the present invention is to provide a planar illuminating lighting device capable of greatly increasing luminance without using a prism sheet.

In addition, The present invention has been made to solve the above-mentioned problems, and an objective of the present invention is to provide a concentrated photovoltaic power generation module which uses the light reflective surface structure, minimizes an area of a solar cell, and has a compact overall size of a solar power generation module combined with a light collecting device and a solar cell.

The objective of the present invention is to provide a concentrated photovoltaic power generation module which can be manufactured simply and inexpensively.

### Technical Solution

To solve above problem, the present invention provides a reflective member 10. If an incident light 61 is introduced to the reflective member 10 in a first direction, a second reflected light 63 magnified in a second direction different from the first direction is emitted, and if an incident light 71 is introduced in the second direction to the reflective member, a second reflected light 73 concentrated in the first direction is emitted.

The reflective member 10 includes a reflective profile surface 13 on which the incident light is reflected; and a first reflective surface 14 and a second reflective surface 15 alternately provided on the surface of the reflective profile surface 13 along a longitudinal direction thereof. The reflective member 10 may further include a film member 11 having a first surface having the reflective profile surface 13 and a second surface opposed to the first surface.

When the incident light 61 is introduced in the first direction, it is incident on the first reflective surface 14. And a first reflected light 62 reflected from the first reflective surface 14 is incident on the second reflective surface 15 which is adjacent to the first reflective surface 14 and closer to the incident direction of the incident light 61 than the first reflective surface 15. And the second reflected light 63 reflected from the second reflective surface 15 intersects the incident light 61 and emits in the second direction.

When the incident light 71 is introduced in the second direction, it is incident on the second reflective surface 15. And a first reflected light 72 reflected from the second reflective surface 15 is incident on the first reflective surface 14 which is adjacent to the second reflective surface 15 and closer to the incident direction of the incident light 71. And the second reflected light 72 reflected from the first reflective surface 14 intersects the incident light 71 and emits in the first direction. Such a reflective member is provided.

The film member 11 is made of a flexible light-transmitting material, and the film member 11 includes a base film layer 17 having a predetermined thickness, and a reflective pattern shaping layer 18 laminated on the surface of the base film 17 to form the reflective profile surface 13, wherein a metal or a reflective ink is applied to the reflective profile surface 13 to form a first reflective surface 14 and a second reflective surface 15.

A connecting surface 16 May be further provided between the first reflective surface 14 and the second reflective surface 15.

The first reflective surface 14 may include a convex, flat or concave surface profile when viewed from a direction in which light is irradiated, and the second reflective surface 15 may include a concave parabolic curved profile when viewed from a direction in which light is irradiated, and a focal point of the parabola may be located near the first reflective surface 14.

In addition, the present invention provides a lighting device in which a light source 30 is arranged on a side surface, a reflective member 10 which is inclined at a very small angle (a) with respect to an incident direction of a light source 30 is installed next to a light source 30, and a predetermined virtual or actual surface arranged on the front surface of the reflective member 10 configures a light emitting surface 20 which emits light. In addition, it provides a lighting device able to emit light with high luminance without the light guide plate and the prism sheet even though a light source 30 is arranged on a side surface, and the light emitting surface 20 and the reflective member 10 are both parallel to the incident direction of the light source 30.

The light emitting surface 20 may be arranged parallel to a representative light emitting direction of the light source 30. And the light emitting surface 20 is parallel to the reflective member 10, or is arranged in parallel with the reflective member 10 while being inclined by a very slight angle (a). Then, it is possible to manufacture lighting device whose entire thickness is thin as much as the thickness (w) of the light source 20 as well as the lighting apparatus has a large area (L) of light emitting surface corresponding to the light emitting surface 20.

The reflective member 10 is manufactured such that a reflective profile surface 13 on which the first reflective surface 14 and the second reflective surface 15 are alternately arranged is formed on the first surface of the UV cured synthetic resin film, and a metal such as aluminum having excellent reflectivity is deposited on the reflective profile surface 13 to a thickness of approximately 0.05 mm to 2.5 mm. More preferably, it may be produced with a thickness of about 0.25 mm to 1 mm. Then, it is possible to realize planar illuminating lighting device by obliquely attaching the film at the side of the light source or attaching the light source to the side of the film.

The first reflective surface 14 reflects the light incident from the light source to the second reflective surface 15, and the second reflective surface 15 reflects the light reflected from the first reflective surface toward the light emitting surface 20.

The first reflective surface 14 may include a convex curved surface, a concave curved surface, or a flat surface as a profile in which light incident on the first reflective surface can be uniformly reflected to the second reflective surface.

The second reflective surface 15 may have a concave curved profile that can reflect light reflected from the first reflective surface to be approximately perpendicular to the light emitting surface 20.

In addition, between the first reflective surface 14 and the second reflective surface 15, and/or between the second reflective surface 15 and the first reflective surface 14, a connecting surface 16 to allow a separation distance between the first reflective surface and the second reflective surface may be further provided.

In particular, such a connecting surface 16 makes it possible to set the angle (a) smaller or to make the luminance near and far from the light source uniform.

In applying the film-shaped reflective member, the first surface of the reflective member, that is, the surface of the reflective profile surface 13 may be used as a reflective surface, or a back surface may be used as a reflective surface. For example, if the reflective profile surface 13 is installed to face the light source, the surface can be used as a reflective surface. In contrast, if the second surface, which is the opposite surface of the first surface, is installed to face the light source, and the film member 11 is made of a light-transmitting material, the rear surface of the reflective profile surface 13 may be used as a reflective surface.

Of course, the present invention does not exclude the use of optical members such as light guide plates and diffusion sheets, etc. According to the present invention, even if a light guide plate and a diffusion plate are not used, a high brightness planar illumination can be realized, and if a light guide plate and a diffusion plate are used in addition to the light guide plate, a higher quality surface emission can be realized. This is clearly distinguished from the existing lighting device which should have a light guide plate and a diffusion sheet for configuring planar light emission.

LEDs may be used as the light source 30.

More specifically, the present invention is a planar illuminating light which includes a reflective member 10 arranged at a predetermined angle (a) of 0 to 45 degrees with respect to a light emitting surface 20; and a light source 30 emitting light toward the reflective member 10 between the light emitting surface and the reflective profile surface 13 of the reflective member 10.

As an example, the incident light 61 is incident on the first reflective surface 14 toward the surface of the reflective profile surface 13 via the medium, and the first reflected light 62 is incident on the second reflective surface 15 toward the surface of the reflective profile surface 13 via the medium, and the second reflected light 63 can be emitted to the light emitting surface 20 via the medium.

Here, the medium may be air or a fluid medium 70.

To this end, the lighting device comprises a housing 80 that includes a light source installation part 81 to which a light source 30 is fixed so that the emitting surface 36 of the light source 30 is disposed between a first end positioned close to the light emitting surface 20 and a second end positioned away from the light emitting surface, and a reflective member mounting surface 82 for fixing the reflective member 10 such that the reflective member faces the light emitting surface 20 and the emitting surface 36 of the light source 30 installed at the light source installation part 81.

The housing 80 may further include a cover 85 for partitioning the medium from an external space of the lighting device and including a transparent material or a diffusion sheet.

In addition, the cover 85 can form the light emitting surface 20.

As another example, the incident light 61 is incident on the first reflective surface 14 toward the rear surface of the reflective profile surface 13 through the second surface of the film member 11 and the film member 11, and the first reflected light 62 is incident on the second reflective surface 15 toward the opposite surface of the reflective profile surface 13 through the film member 11. And the second reflected light 63 is emitted to the light emitting surface 20 through the film member 11 and the second surface.

The planar illuminating lighting device may further include an optical member 50.

The optical member 50 comprises: a light source installation part 81 facing the emitting surface 36 of the light source 30 to receive light from the light source; a reflective member installation surface 82 facing the second surface of the film member 11; and the light emitting surface 20 emitting light reflected from the reflective member 10.

In particular, the light source installation part 81 and the reflective member mounting surface 82 may be adjacent to each other, and the light source installation part 81 and the light emitting surface 20 may be adjacent to each other.

As another example, the incident light 61 is incident on the film member 11 through the side surface of the film member 11 and passes through the film member 10 toward the rear surface of the reflective profile surface 13, and it is incident on the first reflective surface 14. And the first reflected light 62 is incident on the second reflective surface 15 through the film member 11 toward the rear surface of the reflective profile surface 13, and the second reflected light 63 may be emitted through the second surface of the film member 11 to the light emitting surface 20.

As another example, the incident light 61 is incident on the base film layer 17 through the side surface of the base film layer 17, and incident on the reflective pattern shape layer 18 through the base film layer 17 and the interface between the reflective pattern shape layer 18 and the base film layer 17, and incident on the first reflective surface 14 through the base film layer 17 toward the rear surface of the reflective profile surface 13, the first reflected light 62 is incident on the second reflective surface 15 through the reflective pattern shape layer 18 toward the rear surface of the reflective profile surface 13, and the second reflected light 63 may be emitted through the second surface of the film member 11 to the light emitting surface 20.

In the above examples, the predetermined angle (a) may be 0 degrees.

In addition, in the above examples, the second surface may be the light emitting surface 20.

And the light emitting surface 20 may include a diffusion plate.

The refractive index (N1) of the base film layer 17 and the refractive index (N2) of the reflective pattern shaping layer 18 may satisfy a formula of N1=N2.

In addition, it may satisfy the formula of 0.05≤N2−N1≤0.69.

### Effect of the Invention

According to the planar illumination lighting device of the present invention, without optical member such as a light guide plate or an expensive component such as a prism sheet, and even if the high-precision reflective surface is not provided, a planar illuminating lighting device with high-brightness can be embodied with only a reflective member in the form of a film.

Accordingly, the present invention can make the structure of the planar illuminating lighting device very simple, can be easily manufactured at low cost, and can also be manufactured at very light weight.

In addition, by allowing the film layer of the reflective member in the form of a film to have the function of a light guide plate, it is possible to flexibly deform and use the light emitting surface.

According to the photovoltaic power generation module using the light concentrating device of the present invention, the area of the solar irradiation surface of the solar cell 310 can be greatly reduced since parallel solar light incident on a large area is reflected and concentrated on a narrow area through the reflective member 10.

And the reflected concentrated sunlight is also parallel light or close to the parallel light, therefore the sunlight incident on the large area of the photovoltaic module can be concentrated into one solar cell 310 having a small area. Of course, the solar cell 310 can be disposed very close to the reflective member 10, so that it is possible to manufacture the power generation module more compact as a whole compared to the conventional reflection-concentrating or refraction-concentrating solar power module.

In addition, when the solar cell 310 to which the concentrated sunlight is irradiated is configured as a single solar cell 310, there is almost no loss of solar energy compared to the structure in which the solar cells are dispersedly disposed at a plurality of focal points even if the angle at which the concentrated solar light is irradiated is slightly distorted. And the cooling structure can be implemented much more easily and is advantageous for heat harvesting since only one cell needs to be cooled.

In particular, when the power generation efficiency of the photovoltaic module is insensitive to the irradiation angle of the sunlight, the generation efficiency of the photovoltaic module can be further increased regardless of wind.

In addition, since the profiles of the first reflective surface 14 and the second reflective surface 15 of the reflective member 10 can be reflected as parallel light while concentrating sunlight incident on the parallel light, it makes possible to manufacture a solar power module with a very simple structure as well as compactness.

In addition, since the reflective member 10 can be manufactured in a film form, it is possible to configure variously the overall profile of the reflective member 10.

The above and other objects and features of the present invention will become apparent from the following description of the specific embodiments taken in conjunction with the accompanying drawings:

### BRIEF DESCRIPTION OF THE DRAWINGS

FIG. 1 is a cross-sectional view of a first embodiment and a second embodiment of a film-shaped reflective member used in a planar illuminating lighting device or a light-concentrating device according to an embodiment of the present invention.

FIG. 2 and FIG. 3 illustrate the principle of i) making planar illuminating light from a spot light source or ii) concentrating light, through the reflective profile surface of the reflective member of FIG. 1.

FIG. 4 is a cross-sectional view of a third embodiment and a fourth embodiment of a film-shaped reflective member used in a planar illuminating lighting device or a light-concentrating device according to the present invention.

FIG. 5 and FIG. 7 are drawings which illustrate the principle of i) making planar light source from the point light source or ii) concentrating the light, through the reflective profile surface of the reflective member of FIG. 4.

FIG. 6 is a drawing which shows various structures that can be used as a light source of the lighting apparatus of the present invention.

FIG. 8 is an exploded cross-sectional view schematically illustrating a first embodiment of the lighting apparatus of the present invention.

FIG. 9 is a cross-sectional view of an assembled state of the illumination device shown in FIG. 8.

FIG. 10 is an exploded cross-sectional view schematically showing a second embodiment of the lighting apparatus of the present invention.

FIG. 11 is a cross-sectional view of an assembled state of the illumination device shown in FIG. 10.

FIG. 12 is an exploded cross-sectional view schematically showing a third embodiment of the lighting apparatus of the present invention.

FIG. 13 is a cross-sectional view of the assembled state of the illumination device shown in FIG. 12.

FIG. 14 is a partially enlarged view of the third embodiment of FIG. 13.

FIG. 15 is a view showing a process of manufacturing a reflective member used in the fourth embodiment of the present invention.

FIG. 16 is a schematic view showing a structure of a planar illuminating lighting device using the reflective member shown in FIG. 15.

FIG. 17 is a view showing a modified example of FIG. 15, and FIGS. 18 and 19 show a modified example of the reflective member of FIG. 15.

FIG. 20 is an exploded cross-sectional view of a first embodiment of a photovoltaic module to which a light concentrator according to the present invention is applied.

FIG. 21 is a cross-sectional view of the photovoltaic module of FIG. 20.

FIG. 22 is an enlarged view of a portion of the photovoltaic module of FIG. 21.

FIG. 23 is an exploded cross-sectional view of a second embodiment of a photovoltaic module to which a light concentrator according to the present invention is applied, and FIG. 24 is a cross-sectional view of the photovoltaic module of FIG. 23.

FIG. 25 is an enlarged view of a portion of the photovoltaic module of FIG. 24.

FIG. 26 is an exploded cross-sectional view of a third embodiment of a photovoltaic module to which a light concentrator according to the present invention is applied, and FIG. 27 is a cross-sectional view of the photovoltaic module of FIG. 26.

FIG. 28 is a schematic view of a fourth embodiment of a photovoltaic module to which a light concentrating apparatus according to the present invention is applied.

FIGS. 29 and 30 are plan views of the fifth and sixth embodiments of the photovoltaic module to which the light collecting apparatus according to the present invention is applied.

FIG. 31 is a cross-sectional view of a seventh embodiment of a photovoltaic module to which a light concentrator according to the present invention is applied.

### EXPLANATION OF NUMERALS

10, 101, 102, 103, 104, 105 Reflective Member (film) 11: Film member
12: Fixing Surface 13: Reflective Profile Surface 14: First Reflective Surface
15: Second reflective surface 16: connecting surface 17: base film layer
18: Reflective pattern shape layer 19: unit pattern 20: light emitting surface
30: Light Source 31: Light Emitting Unit (LED) 32: Substrate 33: Light concentrating portion
34: Reflection plate 35: lens 36: emitting surface 300: concentrated light receiving portion
310: Solar cell 40: control panel 50: optical elements 61,611,612, 613: incident light
62: Firstly reflected light 63, 631,632, 633: Second reflected light
71, 711, 712, 713: Incident light 72: Firstly reflected light
73, 731, 732, 733: Second reflected light 70: fluid medium
80: Housing 81: Light Source Installation Part 82: Reflective Member Mounting Surface
84: Receiver 85: Cover 90: Optical Adhesive

### DETAILED DESCRIPTION OF THE EXEMPLARY EMBODIMENTS

The present invention will be described in detail with reference to the accompanying drawings.

The present invention may be embodied in many different forms and should not be construed as limited to the embodiments set forth herein; rather, these embodiments are provided so that this disclosure will be thorough and complete, and will fully convey the scope of the invention to those skilled in the art.

[Planar Illuminating and Light Concentrating Principle]

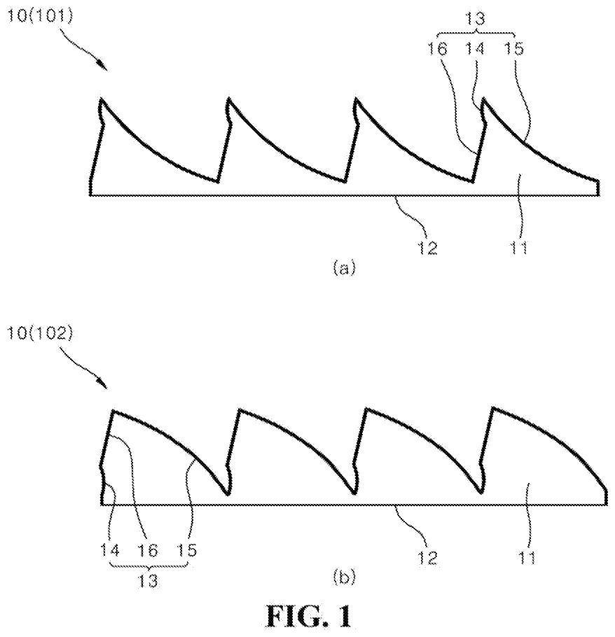

Referring to FIGS. 1 to 6, the principle of implementing the planar illumination of the lighting apparatus and the light concentrating principle of the light concentrating apparatus according to the present invention will be described.

The illumination apparatus of the present invention for embodying planar illumination includes a reflective member 10 for widely diffusing and reflecting light which is obliquely incident to a narrow width. In addition, the light concentrating apparatus of the present invention, which concentrates light incident on a wide area into a narrow width, also includes the reflective member 10. The reflective member 10 may be manufactured in a form of a film. Of course, depending on the type of the article to which the reflective member 10 is applied (a light concentrating device for cooking, a light-concentrating type solar power generation module, the planar illuminating light, etc.), the reflective member 10 may be manufactured in a form other than a film form. For example, the reflective member 10 may be manufactured in the form of a film in a relatively small planar illuminating illumination. In addition, the reflective member 10 may be manufactured in the form of a reflective mirror, for example, in a large solar power generation module.

FIG. 1 shows a partially enlarged view of a reflective member 10 in the form of a film. The film-shaped reflective members 101 and 102 shown in FIGS. 1A and 1B each include a film member 11 having a first surface on which a reflective profile surface 13 is formed and a second surface which is used as a fixing surface 12.

The film member 11 may be made of a synthetic resin material having a high light transmittance while being flexible. This may be a UV curable resin of PE material. The reflective profile surface 13 provided on the upper surface (the first surface) of the film member 11 may be manufactured through surface processing or molded in the step of manufacturing the film with a synthetic resin. The lower surface (the second surface) of the film member 11 may be fabricated with a flat surface so as to be easily-attachable and to prevent scattering and reflection of light that can be incident on the film member 11 through the lower surface in some cases.

The reflective profile surface 13 may be coated with a metal having a very high reflectivity, such as silver or aluminum, through CVD or by sputtering. In addition, a white reflective ink may be applied to the reflective profile surface 13 in a manner such as dipping.

The metal reflective layer coated on the reflective profile surface may reflect light irradiated from the top of the film on front surface of the first surface, as well as reflect the light introduced through the film member at the bottom of the film on the rear surface of the first surface. The film shown in FIG. 1A is a structure in which light is reflected from the front surface of the first surface, and the film shown in FIG. 1B is a structure in which light is reflected from the rear surface of the first surface. Both reflective profile surfaces are easy to manufacture.

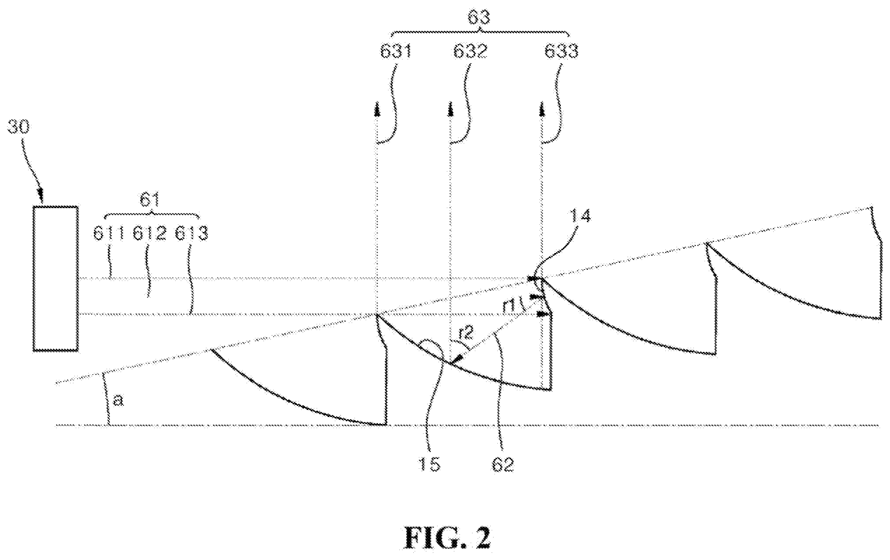

FIG. 2 shows the principle that light having a narrow area is magnified largely into a planar illumination by the reflective profile surface 13 of the film shown in FIG. 1.

First reflective surfaces 14 and second reflective surfaces 15 are alternately arranged in the reflective profile surface 13, and connecting surfaces 16 are further provided for adjusting a distance or a position between the reflective surfaces as needed.

The light source 30 may irradiate light obliquely from the lateral side of the reflective member 10 toward the reflective member 10. The reflective member 10 may be inclined at a slight angle (a) with respect to the light source. In FIG. 2, the light source 30 emits light in the horizontal direction, and the reflective member 10 reflects the light vertically upward, so that the light emitted from the light source 30 is magnified. In theory, the light emitting area of the reflective member 10 compared to the light emitting area of the light source 30 can be increased by cotangent a.

As described above, the reflective surface 10 faces both the emitting surface 36 of the light source 30 and the light emitting surface 20. That is, the reflective surface of the reflective member 10 is arranged in the form of an inclined surface which is disposed at an angle with respect to an incident direction of the light source 30 and is also disposed at an angle with respect to the light emitting surface 20.

When the reflective member 10 is inclined by an angle a and is obliquely installed next to the light source 30, only a plurality of first reflective surfaces 14 are exposed when the reflective member 10 is viewed from the light source 30 in a horizontal direction. When the reflective member 10 is viewed vertically downward from the top of the drawing, only a plurality of second reflective surfaces 15 are exposed.

In FIG. 2, the light source 30 emits light horizontally, and a shape in which the reflective member 10 is inclined by a predetermined angle (a) is shown, but this is a relative concept. That is, the light source 30 is installed in the horizontal direction by a predetermined angle (a), and the reflective member 10 may be disposed horizontally. Accordingly, the pattern of the reflective surface of FIG. 2 can also be slightly tilted (see FIG. 19).

The convex curved surface of the first reflective surface 14 uniformly disperses and reflects incident light 61(611,612, and 613) parallelly incident to the first reflective surface 14 in a horizontal direction from the light source 30 toward the first reflective surface 14. The first reflected light 62 reflected from the first reflective surface is reflected substantially vertically upward from the second reflective surface 15 which is a concave curved surface. That is, the second reflected light 63 (631, 632, 633) reflected from the second reflective surface 15 becomes more widely distributed parallel light.

The smaller the installation angle a of the reflective member 10, the larger the planar illuminating enlargement area. The connecting surface 16 can set a wider distance between the first reflective surface 14 and the second reflective surface 15 of the reflective member 10, and can set a distance between the two reflective surfaces 14 and 15 in a vertical direction as well as a horizontal direction. The connecting surface 16 makes it easy to make the installation angle (a) of the reflective member 10 much smaller while do not participate in the reflection. The connecting surface 16 is shown in FIG. 2 in a form that does not function as the intended reflective surface. However, since the light irradiated from the light source is not completely parallel light, the surface of the connecting surface 16 can also participate in the reflection.

Farther from the light source, narrower the connecting surface 16 between the first reflective surface 14 and the second reflective surface 15. In other words, since the light emitted from the light source tends to diffuse itself, the area of the first reflective surface 14 can be gradually increased as a distance from the light source becomes greater.

FIG. 2 shows a structure in which a connecting surface 16 is located between the first reflective surface 14 and the second reflective surface 15, which transmit and receive reflected light to each other. But the connecting surface 16 may be located between the second reflective surface 15 and the first reflective surface 14, which do not transmit and receive reflected light to each other while are neighbored to each other. And the connecting surfaces 16 may be located at both.

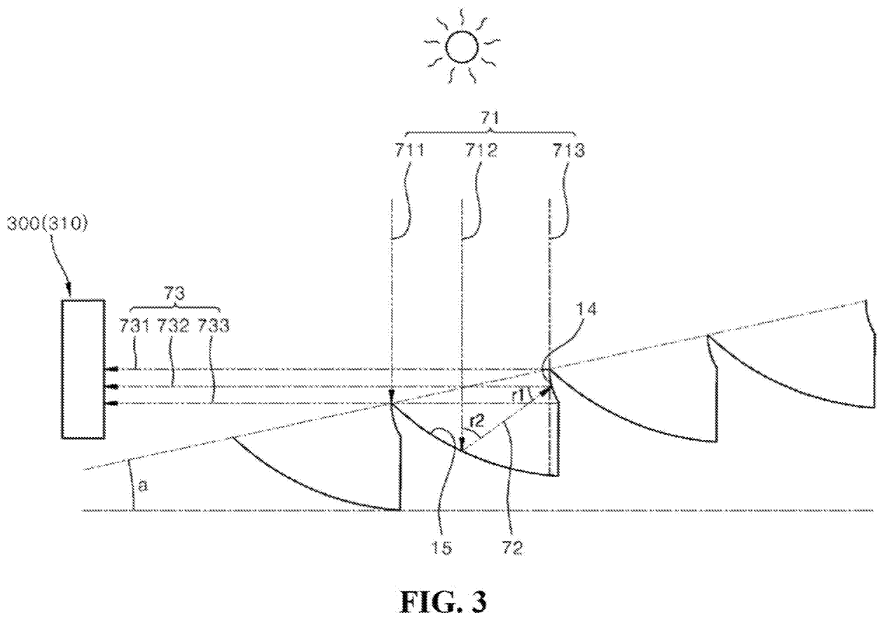

FIG. 3 shows a principle that a large area of light is concentrated by the same reflective profile surface 13 as shown in FIG. 2.

The concentrated light receiving portion 300, such as the solar cell 310, may be disposed so as to face the reflective member 10 at an angle from the side of the reflective member 10. The reflective member 10 may be inclined at a slight angle (a) with respect to the concentrated light receiving portion 300. As shown in FIG. 3, the reflective member 10 reflects the sunlight in the vertical direction in a wide area, and concentrates the reflected sunlight in a horizontal direction on the concentrated light receiving portion 300 having a narrow area. In theory, the light concentrating area toward the concentrated light receiving portion 300, compared to the area of the sunlight reflected by the reflective member, can be concentrated (reduced) by cotangent a.

As described above, the reflective surface 10 is installed so that the reflective surface of the reflective member 10 faces the sun and simultaneously faces the concentrated light receiving portion 300. That is, the reflective surface of the reflective member 10 is disposed at an angle with respect to the incident direction of the sunlight, and is arranged in the form of an inclined surface disposed at an angle with respect to the concentrated light receiving portion 300.

When the reflective member 10 is inclined by an angle (a) and is obliquely installed next to the concentrated light receiving portion 300, only a plurality of first reflective surfaces 14 are exposed when the reflective member 10 is viewed in a horizontal direction from the concentrated light receiving portion 300. When the reflective member 10 is viewed vertically downward from the upper portion (the solar position), only the plurality of second reflective surfaces 15 are exposed.

The concave curved surface of the second reflective surface 15 collimates and reflects incident light 71 (711, 712, and 713) parallelly incident toward the second reflective surface 15 in a vertical direction to the first reflective surface 14. And the first reflected light 72 reflected from the second reflective surface are all reflected from the convex curved first reflective surface 14 into a substantially horizontal direction. That is, the second reflected light 73 (731,732, and 733) reflected from the first reflective surface 14 becomes substantially parallel light distributed much narrowly.

The smaller the installation angle (a) of the reflective member 10, the greater the light concentration. The connecting surface 16 can set a wider distance between the first reflective surface 14 and the second reflective surface 15 of the reflective member 10, and can set a distance between the two reflective surfaces 14 and 15 in a vertical direction as well as a horizontal direction. The connecting surface 16 makes it easy to make the installation angle (a) of the reflective member 10 smaller while not participating reflection. The connecting surface 16 in FIG. 3 is shown in a form that does not function as the intended reflective surface. However, since the light collected from the second reflective surface 15 may not be completely coliminated to the first reflective surface 14, the surface of the connecting surface 16 may also participate in the reflection.

Although FIG. 3 shows a structure in which the connecting surface 16 is located between the first reflective surface 14 and the second reflective surface 15, which transmit and receive the reflected light to each other, the connecting surface 16 may be positioned between the second reflective surface 15 and the first reflective surface 14, which do not transmit and receive the reflected light but neighboring to each other or be positioned at both.

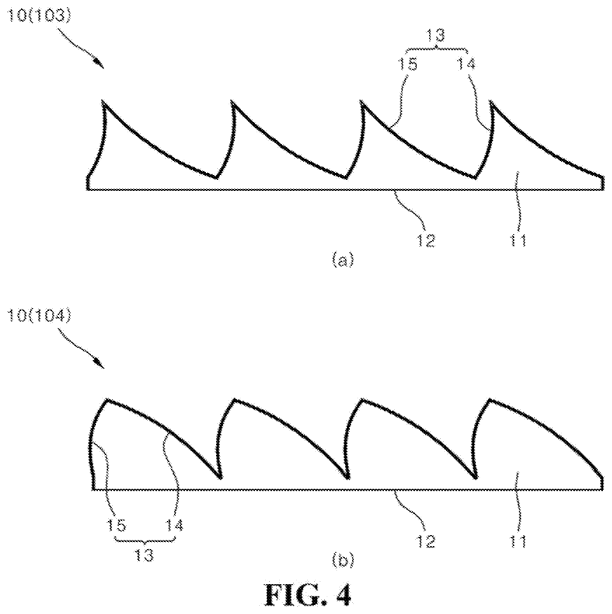

FIG. 4 is a partially enlarged view of another embodiment of a reflective member 10 in the form of a film. The film-shaped reflective members 103 and 104 shown in FIGS. 4A and 48, respectively, include a film member 11 having a first surface on which a reflective profile surface 13 is formed, and a second surface, which is used as a fixing surface 12.

The reflective layer coated on the reflective profile surface 13 may also reflect light emitted from the top of the film on the front surface of the first surface, as well as reflect the light introduced through the film member at the bottom of the film on the back surface of the first surface. The film shown in FIG. 4A is a structure for reflecting light at the front surface of the first surface, and the film shown in FIG. 4B is a structure for reflecting light at the back surface of the first surface. Both reflective profile surfaces are easy to manufacture.

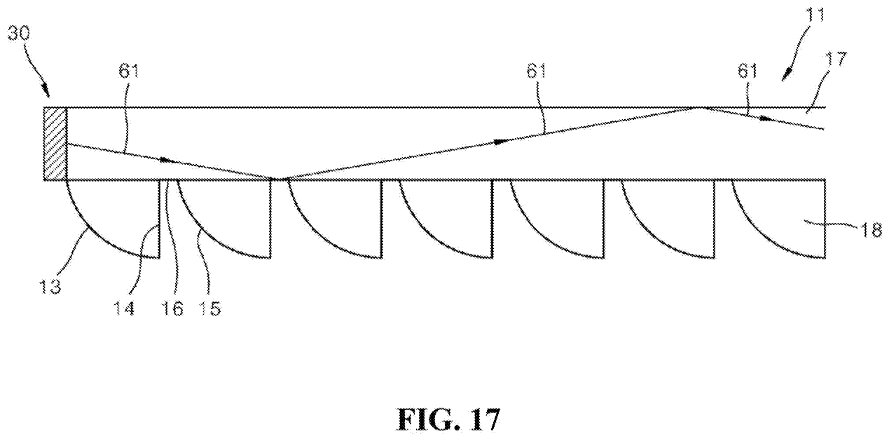

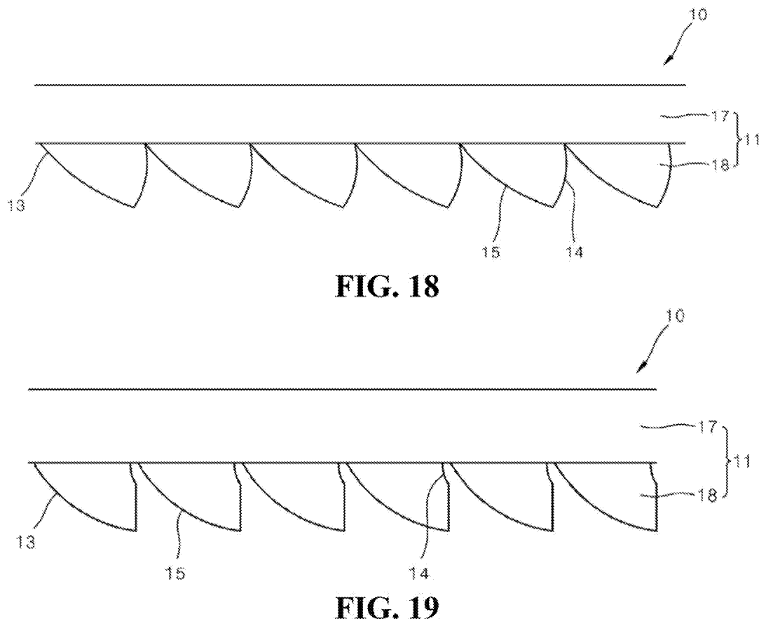

The first reflective surfaces 14 and the second reflective surfaces 15 are alternately disposed at the reflective profile surface 13. In the embodiment shown in FIG. 4, there is shown an example in which the connecting surface 16 for adjusting the distance or position between the reflective surfaces (see FIG. 17) is not provided.

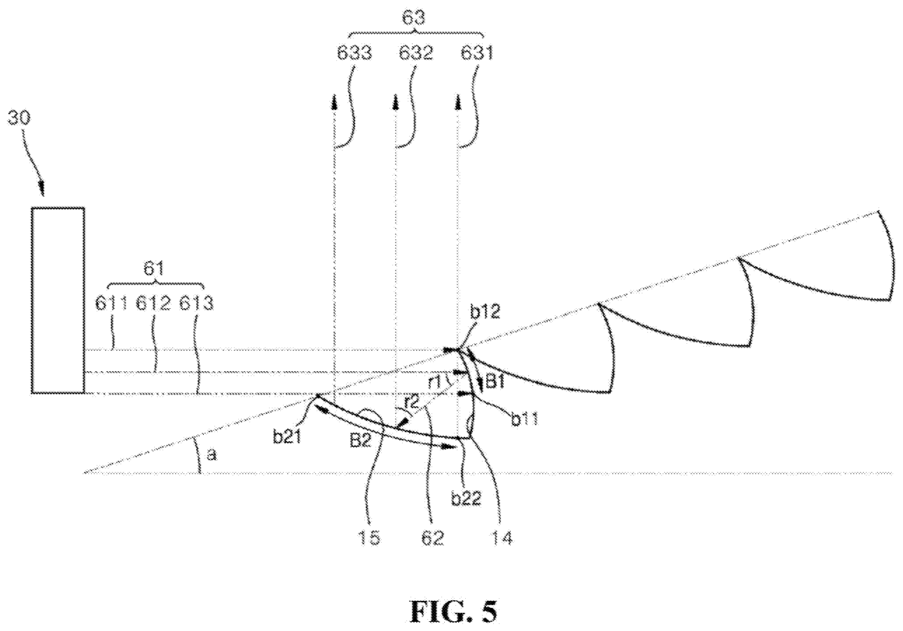

Referring to FIG. 5, the light source 30 irradiates light in the horizontal direction from the lateral side of the reflective member 10, and the reflective member 10, which is obliquely installed next to the light source 30, reflects the light vertically upward, so that the light emitted from the narrow area becomes wider planar light.

When the reflective member 10 is inclined by an angle “a” and is obliquely installed next to the light source 30, only a plurality of first reflective surfaces 14 are exposed when the reflective member 10 is viewed from the light source 30 in a horizontal direction. When the reflective member 10 is viewed vertically downward from the top of the drawing, only a plurality of second reflective surfaces 15 are exposed.

In FIG. 5, the light source 30 emits light horizontally, and a shape in which the reflective member 10 is inclined by a predetermined angle “a” is shown in FIG. 5, but this is a relative concept. That is, the light source 30 is installed facing downward at a predetermined angle (a) with respect to the horizontal direction, and the reflective member 10 may be disposed horizontal. As a result, the pattern of the reflective surface of FIG. 5 can also be slightly tilted (see FIG. 18). In addition, when the reflective member itself functions as a light guide, the light source may be horizontally disposed and the reflective member may be horizontally disposed.

The concave curved surface of the first reflective surface 14 uniformly disperses and reflects incident light 61(611,612, and 613) incident parallelly to the first reflective surface 14 in a horizontal direction from the light source 30 toward the first reflective surface 14. The first reflected light 62 reflected from the first reflective surface is reflected substantially vertically upward from the concave curved second reflective surface 15. That is, the second reflected light 63(633,632, and 631) reflected by the second reflective surface 15 becomes more widely distributed parallel light.

The two reflective surfaces 14 and 15, which are adjacent to each other to transmit and receive reflected light, are repeatedly installed as an unit, and a connecting surface may be disposed between the units, may be disposed within the unit, or may be both disposed within the unit and between the units.

Either the first reflective surface is a convex curved surface and the second reflective surface is a concave curved surface as shown in FIG. 1 and both the first reflective surface and the second reflective surface are concave curved surfaces as shown in FIG. 4, sum of the angle r1 by which the incident light 61 emitted from the light source is reflected at the first reflective surface 14 and the angle r2 by which the first reflected light 62 reflected from the first reflective surface 14 is reflected at the second reflective surface 15 is set to be close to 90 degrees or to 90 degrees. For example, if the reflection angle r1 of the first reflected light 62 is 89 degrees (see 613 of FIG. 2, see 611 in FIG. 5), the reflection angle r2 of the second reflected light is 1 degree (see 633 of FIG. 2, see 631 in FIG. 5). If the reflection angle r1 of the first reflected light is 45 degrees (see 612 of FIG. 2, see 612 of FIG. 5), the reflection angle r2 of the second reflected light is 45 degrees (see 632 of FIG. 2, see 632 in FIG. 5). If the reflection angle r1 of the first reflected light is 1 degree (see 611 of FIG. 2, see 613 of FIG. 5), the reflection angle r2 of the second reflected light is 89 degrees (see 631 of FIG. 2, see 633 in FIG. 5).

In order to satisfy this rule, for example, referring to FIG. 5, it is desirable for the first reflective surface to have a profile such that the slope of the first point b11 of the first reflective surface area B1 on which the incident light 61 is incident is 90 degrees and the slope of the second point b12 of the first reflective surface area B1 on which the incident light 61 is incident is −45 degrees, and in order to make the angle (a) very small, it is desirable for the first reflective surface to have a concave profile.

In addition, it is preferable for the second reflective surface to have a profile such that the slope of the first point b21 of the second reflective surface area B2 on which the first reflected light 62 is incident is −45 degrees and the slope of the second point b22 of the second reflective surface area B2 on which the first reflected light 62 is incident is 0 degree, and the second reflective surface has a concave profile in order to make the angle (a) very small.

The profile of the reflective surface can be set by a similar principle even in the case of FIG. 2. As a result of a research by the inventor, when the first reflective surface is convexly formed as shown in FIG. 1 as compared to the concave first reflective surface as shown in FIG. 4, it is possible to construct the first reflective surface more compactly. In addition, if the first reflective surface has a convex profile, even if the degree of parallelism of the incident light of the light source 30 is somewhat less than that of the concave-convex profile, the light reflected from the second reflective surface can be more uniformly spread, thereby easily having a planar illuminating effect.

On the other hand, even if the first reflective surface 14 is not convex or concave and forms a flat planar surface, it is possible to implement planar illumination as contemplated by the present invention. Since the planar illumination of the light is not necessarily implemented only when the light is incident perpendicular to the light emitting surface 20, there is no problem in constructing the reflective profile surface 13 for implementing the surface emission even if the first reflective surface 14 is flat.

If the profile of the first reflective surface and the second reflective surface is set to have above mentioned reflection angle, making planar illumination in a shape of parallel light in a reflective manner without an optical member such as a light guide plate or a diffusion plate, which occupies a small space, is possible. To satisfy these conditions and to form a small inclination angle (a) of the reflective member 10, the lighting device can be manufactured slim, and it is possible to implement planar illumination lighting by expanding the light emitting area at a ratio of cotangent a.

In the lighting device, the light source 30 and the reflecting member 10 are installed in a housing 80 to be described later and fixed relative to each other, or assembled to an optical member 50 and fixed relative to each other. In addition, the light source 30 may be directly fixed to the reflective member 10.

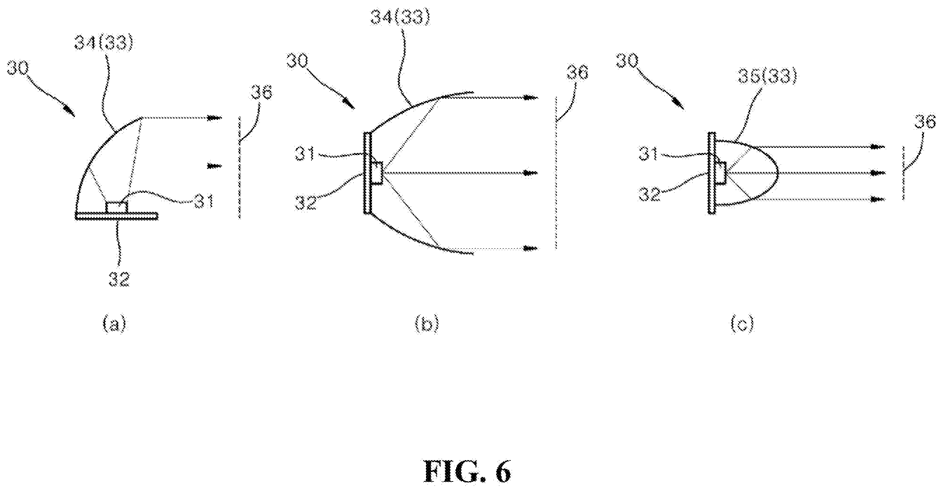

Rather than the light irradiated from the LED, which is the light emitting unit 31 mounted on the substrate 32, directly enters the reflective member 10, the light incident from the light source (30) on the reflective member 10 may be in the form of parallel light in some extent through a light concentrating portion 33 such as a reflector 34 or a lens 35 as shown in FIG. 6. At this time, the direction of the light emitting unit 31 is arranged to face the reflective member 10 as shown in FIG. 6(b) or FIG. 6(c), or it may be arranged to face a planar illuminating surface as shown in FIG. 6(a), or may be disposed with the reflective member 10 behind. In addition, the reflection plate 34 may be provided on one side as shown in FIG. 6(a) or on both sides as shown in FIG. 6(b), and the lens 35 may be integrally packaged on the substrate.

The light concentrated and paralleled to some extent is emitted through a emitting surface 36 of the light source and is incident on the reflective member 10.

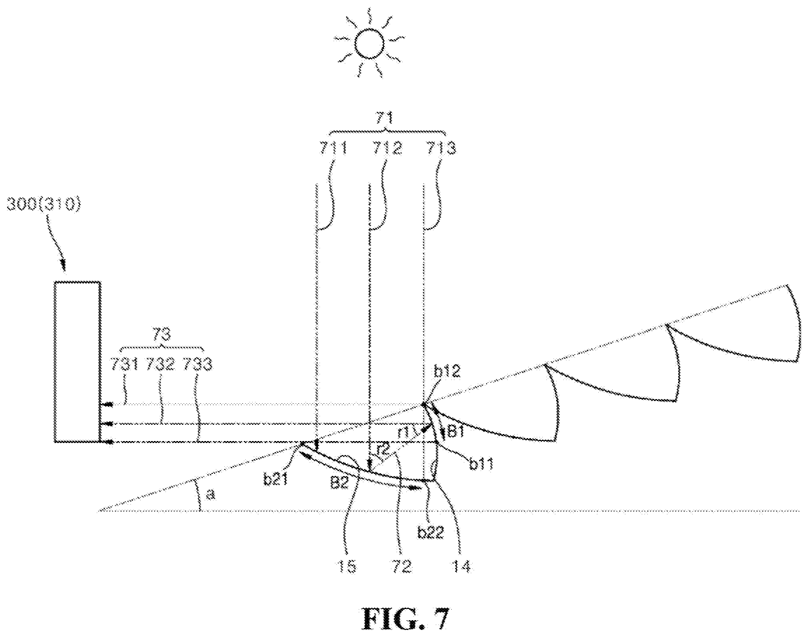

FIG. 7 shows a principle that a large area of light is concentrated by the same reflective profile surface 13 as shown in FIG. 4. Referring to FIG. 7, the concentrated light receiving portion 300 faces the reflective profile surface 13 in a horizontal direction from the lateral side of the reflective member 10, and the sunlight irradiated from the vertical upper portion is reflected into a horizontal direction by the reflective member 10, thereby concentrate the sunlight irradiated in a wide area narrowly.

When the reflective member 10 is inclined by an angle (a) and is obliquely installed next to the concentrated light receiving portion 300, only a plurality of first reflective surfaces 14 are exposed when the reflective member 10 is viewed in a horizontal direction from the concentrated light receiving portion 300. When the reflective member 10 is viewed vertically downward from the top of the drawing, only a plurality of second reflective surfaces 15 are exposed.

The concave curved second reflective surface 15 reflects and concentrates parallelly incident light 71(711,712, and 713), which is incident to the second reflective surface 15 in a vertical direction, toward the first reflective surface 14. The first reflected light 72 reflected from the second reflective surface are all reflected at the concave curved first reflective surface 14 into a substantially horizontal direction. That is, the second reflected lights 73 (733,732, and 731) reflected by the first reflective surface 14 are more widely narrowly concentrated.

As shown in FIG. 1, when the first reflective surface is a convex curved surface and the second reflective surface is a concave curved surface, and as shown in FIG. 4, when both the first reflective surface and the second reflective surface are concave curved surfaces, in any case, the sum of the angle r2 by which the incident light 71 emitted from the sun is reflected at the second reflective surface 15 and the angle r1 by which the first reflected light 72 reflected from the second reflective surface 15 is reflected at the first reflective surface 14 can be set to be close to 90° or to be 90°. Since the principle is the same as described above, repeated description is omitted.

By setting the profiles of the first and second reflective surfaces to have the above-described reflection angle, it is possible to concentrate light in a parallel light type by a reflective manner while occupying a narrow space. To satisfy these conditions and to form a small inclination angle (a) of the reflective member 10, the light collecting device can be manufactured slim, and it is possible to increase the light concentrating rate at a ratio of cotangent a.

On the other hand, by making the second reflective surface 15 have a parabolic form, when concentrating light as shown in FIGS. 3 and 5, the sunlight is reflected from the second reflective surface and concentrated on the first reflective surface, and when diffusing light as shown in FIGS. 2 and 4, the first reflected light reflected from the first reflective surface is reflected in the form of parallel light at the second reflective surface to become the second reflected light. The conic constant of the parabola may be −0.8 to −1.2, and specifically −1.

The first reflective surface and the second reflective surface may be a non-spherical surface, that is, not a profile of a circle or an ellipse.

<Lighting Device>

### First Embodiment

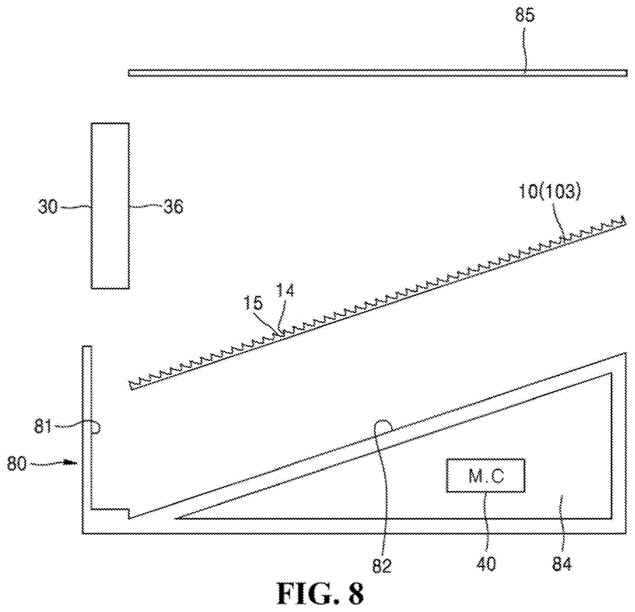

Referring now to FIG. 8, a first embodiment of a lighting device to which the principles of the present invention is applied will be described. In the first embodiment, the reflective member 101, 103 as shown in FIG. 1(a) or FIG. 4(a), ie, a structure in which reflection occurs at the front surface of the reflective profile surface 13, is illustrated.

The light source 30 and the reflective member 10 are installed in the housing 80, and the position of the light source 30 and the reflective member 10 may be fixed to each other.

The housing 80 includes a light source installation part 81 in which the light source 30 is installed, and a reflective member mounting surface 82 on which the reflective member 10 is installed. In addition, a space having a rectangular cross-section provided on the rear surface of the reflective member mounting surface 82 may be a receiving portion 84 in which a control unit 40 for controlling the light source 30 is installed.

The housing 80 may define a approximately rectangular parallelepiped space having a width of L and a depth of W.

One flat reflective surface just reflects the incident light by an reflection angle and does not have an effect of concentrating light. In addition, a reflective surface, such as a convex mirror, disperses incident light, but it is not suitable for planar illumination since it is not a parallel light type. A planar illumination method using an optical member such as a light guide plate, a large portion of light is reflected or disappeared while light passes between a denser medium and a rarer medium, and there is a problem in that manufacturing cost and lighting weight increase.

However, the illumination apparatus according to the present invention has a structure in which the light-emitting area of the light source is enlarged by cot a=L/w, and is completed by simply attaching the film-type reflective member 10 by an angle of “a” at the lateral side of the light source 10 which emits light in the lateral direction.

In addition, the space corresponding to the right triangle part can be used as the accommodating part 84 of the housing 80, and it is possible to install various electric components such as the control part 40 in this part, so that it is possible to design a compact and slim planar illuminating lighting device.

In addition, a cover 85 covering the light source and the reflective member is further installed at a position corresponding to the light emitting surface 20 of the lighting device, so that foreign materials can be prevented from flowing into the surface of the reflective member.

The cover 85 may be simply made of a transparent material, or may be manufactured for dispersing light like rough glass, or may be made of a diffusion plate material. The cover 85 having a diffusion plate-like structure may further improve the planar illumination quality. Of course, since the planar light is already emitted by the reflective member, the cover 85 can be omitted.

### Second Embodiment

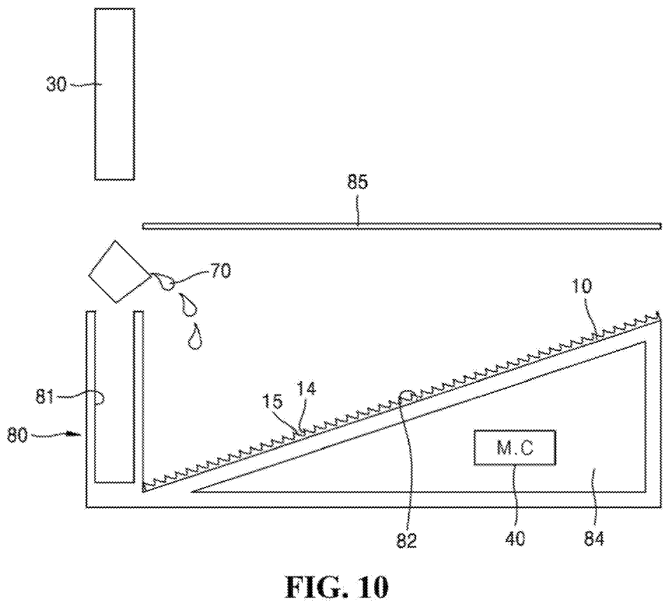

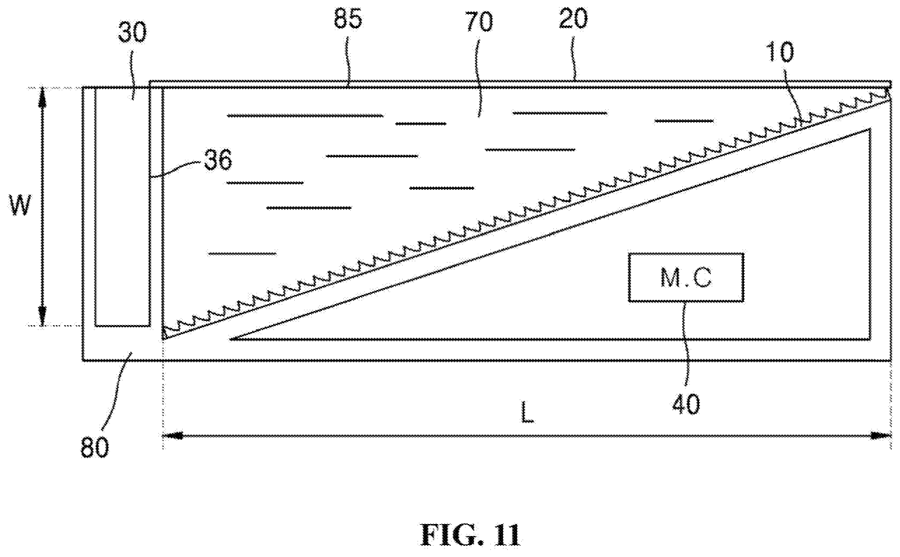

Referring now to FIGS. 10 and 11, a first embodiment of a lighting apparatus to which the principles of the present invention is applied will be described. In the description of the second embodiment, the description of what overlaps with the first embodiment will be omitted.

In the second embodiment, in addition to the first embodiment, an optical structure is implemented by filling a fluid medium 70 such as a liquid between the front surface of the reflective member 10 and the cover 85.

According to the second embodiment, after the reflective member 10 is installed in the housing 80, the fluid medium 70 is filled in the front space of the reflective member 10 and is sealed with a cover 85 so that the fluid medium 70 is not leaked. Then, the fluid medium 36 is filled into the space between the patterns of the first reflective surface 14 and the second reflective surface 15.

The light source 30 can be replaceable regardless of the space filled with the fluid medium 70.

According to the second embodiment, the light from the light source 30 passes through the fluid medium 70 and reaches the surface of the first reflective surface 14 of the reflective member 10.

The incident light reaching the surface of the first reflective surface 14 is reflected and is incident on the second reflective surface 15 adjacent to the first reflective surface 14 through the fluid medium 70. Then, the second reflected light reflected from the second reflective surface 15 is reflected as substantially parallel light, passes through the fluid medium 70 and is emitted as illumination light through the light emitting surface 20.

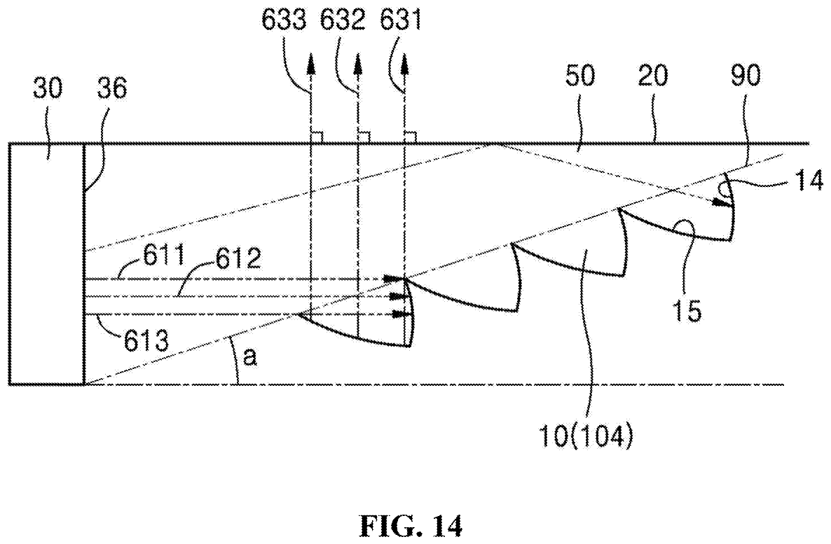

According to the above structure, the surface of the reflective member 10 can be prevented from being contaminated. In addition, it has an advantages that the incident light irradiated with a slight error in the light source 30 is totally reflected from the light emitting surface 20 of the fluid medium 70 or the cover 85 to be incident on the reflective member 10 (see FIG. 14). Above all, such a structure is better in that it can have a similar effect to the light guide plate without an expensive optical member such as a light guide plate.

In order to minimize reflection and refraction from occurring at the interface between the cover 85 and the fluid medium 70, the density of the cover and fluid medium is preferably set to be similar to each other. That is, a material of each medium can be adopted to have a similar density to each other. In order to minimize the occurrence of reflection and refraction at the interface between the cover 85 and the fluid medium 70, the density of the cover and the fluid medium is preferably set to be similar to each other. That is, it is possible to adopt materials of each medium to have similar densities.

### Third Embodiment

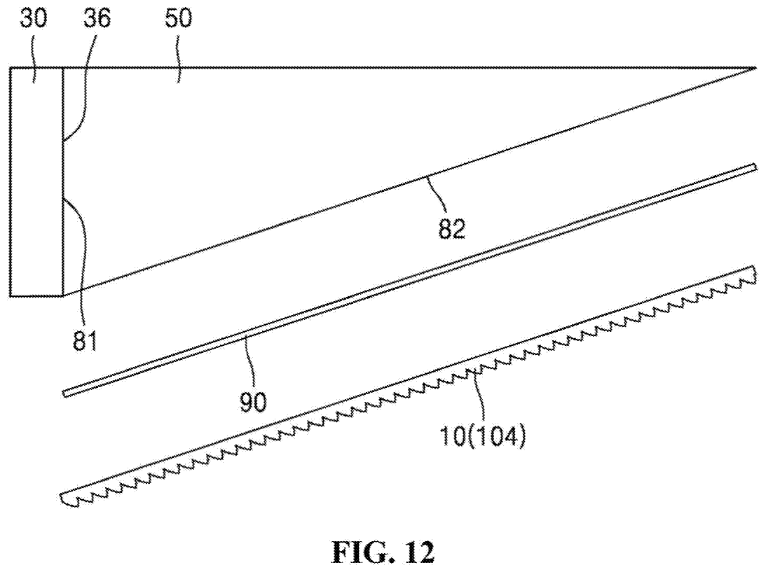

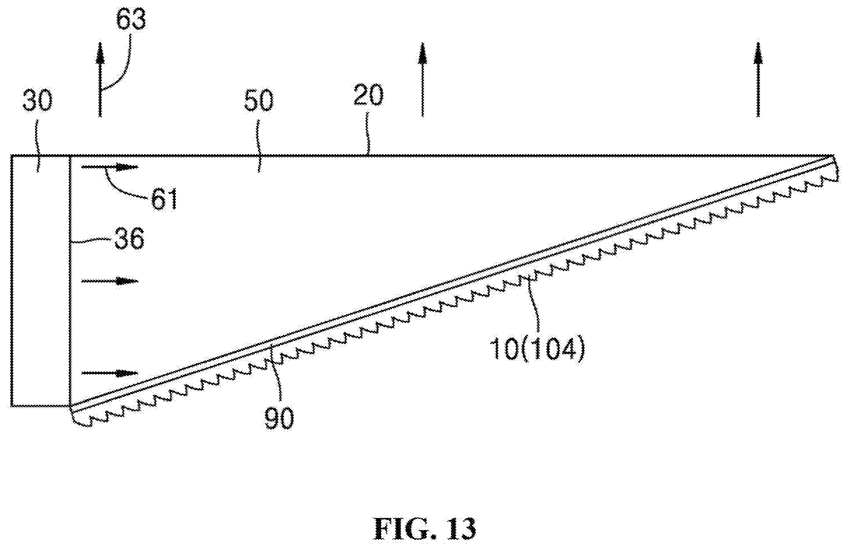

Referring now to FIGS. 12 to 14, a third embodiment of a lighting apparatus to which the principles of the present invention is applied will be described. In the third embodiment, the reflective member 102, 104 as shown in FIG. 1(b) or FIG. 4(b), that is, a structure in which reflection occurs at the back surface of the reflective profile surface 13, is illustrated.

In the third embodiment, the optical member 50 is installed in a space where the reflective member 10 and the light source 30 face each other. The optical member is provided with a light source installation part 81, a reflection member installation surface 82, and a light emission surface 20. These are different points compared with the light source 30 and the reflective member 10 are installed in the housing 80. The optical member 50 may be made of a material having a good light transmittance, such as acrylic. In addition, the emitting surface 36 of the light source 30 and the light emitting surface 20 of the lighting device are perpendicular to each other so that the optical member 50 is made as a structure with a long right-angled triangular cross section

The optical member 50 and the reflective member 10 can be bonded by interposing an optical adhesive (OCR/OCA) 90 having a similar density to the optical member and good transmittance.

In addition, in the third embodiment, the reflection of the reflective member 10 is occurred on the back surface of the reflective member 10 rather than the surface of the reflective member 10. That is, in the film constituting the reflective member 10 of the third embodiment, the reflective surface becomes the back surface of the first surface, that is, the back surface of the reflective profile surface 13. The light emitted from the light source 30 passes through the optical member 50, the optical adhesive 90, and the film member 11, and reaches the first reflective surface 14 of back of the reflective profile surface 13.

Since aluminum is deposited on the surface of the synthetic resin film in which the reflective surface profile is formed on the surface of the reflective member, reflection can occur even if the light is irradiated on the rear surface of the reflective surface profile by passing the synthetic resin part of the film on the back side of the film as well as light is irradiated directly on the reflective surface profile from the outside of the film.

The incident light reaching the rear surface of the first reflective surface 14 is reflected and is incident on the rear surface of the second reflective surface 15 through the synthetic resin portion of the film member 11. The second reflected light reflected from the back surface of the second reflective surface 15 is reflected as substantially parallel light, and is irradiated to the outside of the lighting apparatus through the light emitting surface 20 through the synthetic resin portion of the film member, the optical adhesive 90, and the optical member 50.

In order to minimize reflection and refraction from occurring at the interface between the film member and the optical adhesive, and at the interface between the optical adhesive and the optical member, the density of the film member and the optical adhesive and the optical member are preferably set to be similar to each other. That is, a material of each medium can be adopted to have a similar density to each other.

According to the third embodiment, since the light source 30 and the reflective member 10 can be fixed by the optical member 50, it is possible to omit the configuration of the housing 80 as illustrated in the first embodiment, or to manufacture the housing 80 in a different form.

When the optical member 50 is installed as in the third embodiment, it is possible to prevent the back side of the reflective profile surface 13, which becomes the reflective surface of the reflective member 10, from being contaminated. In addition, as shown in FIG. 14, the incident light irradiated with a slight error in the light source 30 is totally reflected from the light emitting surface 20 of the optical member 50 or the cover 85 to be incident on the reflective member 10

In the third embodiment shown, the predetermined angle (a) is a small acute angle, but the predetermined angle may be 0 degrees. That is, even when the reflective member 10 and the light emitting surface 20 are parallel, since the light emitted from the light source 30 is not completely parallel light but is diffused, the light emitted from the light source 30 is reflected at last through the reflective member 10 and can be used as illumination light through the light emitting surface 20.

That is, in the present invention, the fact that the light source 30 emits parallel light does not mean parallel light such as sunlight, but rather means that light reaching the light emitting surface 20 directly from the light source 30 can be totally reflected from the light source 30 and returned to the reflective member 10 as shown in FIG. 14, that is, light spreading at an angle greater than the total reflection threshold angle.

Unlike the conventional light guide plate, the optical member of the third embodiment does not perform panel processing by printing or laser patterning under the light guide plate. Therefore, the material itself may be similar to the conventional light guide plate, but it should be noted that there is no need to perform any panel processing that causes a price increase.

### Fourth Embodiment

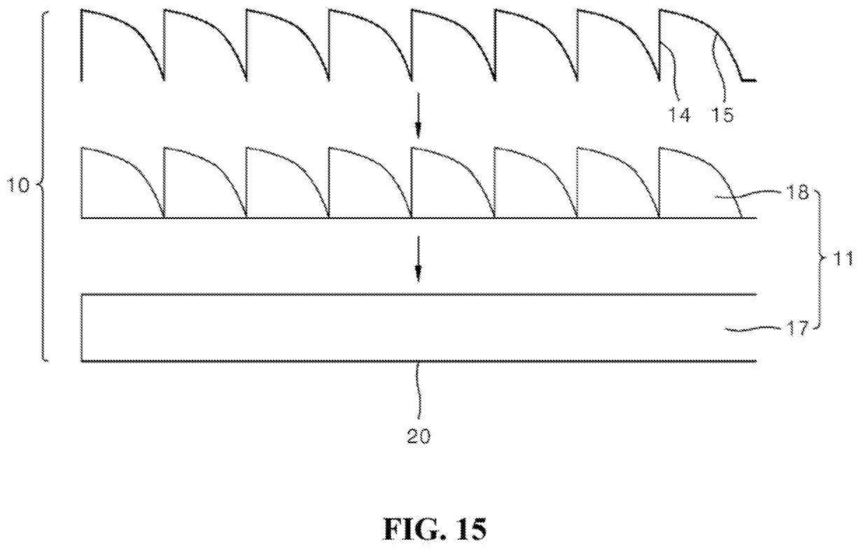

Referring now to FIGS. 15 to 19, a fourth embodiment of a lighting apparatus to which the principles of the present invention is applied will be described. In the fourth embodiment, as shown in FIG. 1(b) or FIG. 4(b), the reflective member 102, 104, that is, a structure in which reflection occurs at the back surface of the reflective profile surface 13, is applied, and the light is incident on the side surface of the reflective member so that the film member constituting the reflective member itself functions as a light guide.

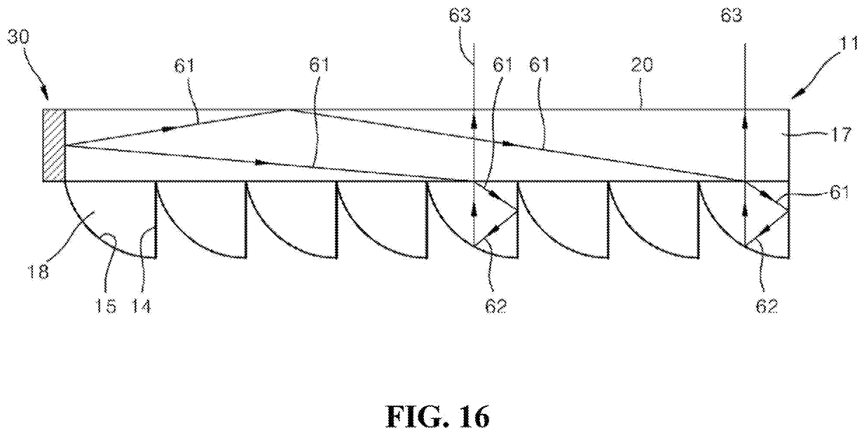

Referring first to FIGS. 15 and 16, the reflective member 10 is manufactured in the form that a reflective layer is deposited, coated, or painted on the reflective profile surface 13 of the film member 11. The film member 11 May be fabricated from two or more different layers. According to the present invention, it is convenient to manufacture, and the brightness of the light emitted from the light emitting surface 20 can be increased by finally increasing the straightness of the light emitted from the light emitting surface 20 through the refraction of the light incident on the reflective surface at the interface of the different material layers.

The film member 11 can be manufactured by laminating the reflection pattern forming layer 18 constituting the reflective profile surface 13 on the base film layer 17 having a predetermined thickness (on the order of about 0.5 mm) with a mold resin and UV curing. The base film layer 17 may be a flexible material such as polycarbonate (PC). Accordingly, the film member 11 can be manufactured in the form of a flexible sheet.

The reflective pattern forming layer 18 may be formed by molding a soft synthetic resin on the base film layer 17 and then UV curing. A reflective layer may be coated on the reflective profile surface 13 on which the reflection pattern forming layer 18 is stacked on the first surface of the base film layer 17. The reflective layers 14 and 15 may be coated by depositing silver, aluminum, etc. which form a reflective surface, or by applying a reflective ink.

The base film layer 17 and the reflection pattern forming layer 18 may be made of the same or different materials. According to the fourth embodiment, each material may be selected such that the refractive index of the base film layer 17 is less than or equal to the refractive index of the reflection pattern forming layer 18, that is, N1≤N2.

According to the fourth embodiment, if the refractive index of the base film layer is greater than the refractive index of the reflection pattern forming layer, ie, N1>N2, a portion of the light incident from the base film layer to the reflection pattern forming layer, of which the incident angle is larger than the critical angle, is not incident on the reflection pattern forming layer, thereby reducing the amount of light that reflects the light through the double reflective surface to the light emitting surface (20).

Even though the predetermined angle (a) of the reflective member 10 is 0 degrees with respect to the light emitting surface 20, that is, even though the film member 11 and the light emitting surface 20 are parallel, the planar illumination can brighter. In other words, in the above embodiments, a predetermined angle (a) of about 2 to 3 degrees is to secure the angle of light incident on the first reflective surface 14 to some extent. If a refraction occurs between the base film layer and the reflection pattern forming layer and the refraction occurs at an interface where the refractive index of the reflection pattern forming layer is larger than that of the base film layer, the angle of light incident on the first reflective surface 14 can be additionally secured by refraction at the interface.

Therefore, as shown in FIG. 16, even though the second surface of the film member 11 forms the light emitting surface 20 and the first surface of the film member 11 on which the reflective surfaces 14 and 15 of the film member 11 are formed is parallel to the second surface and the light source 30 irradiates light in a direction parallel to the first surface and the second surface from the side surface of the film member 11 between the first surface and the second surface, the refraction is generated, thereby having an effect similar to tilting the reflective member by a predetermined angle.

The light source 30 may be a thin light source corresponding to the thickness of the film member, which may be implemented as an LED. The light source 30 emits light that is slightly diffused, rather than a fully parallel light source, in which incident light 61, which is incident on the second surface of the film member 11, is totally reflected from the second surface to reach the interface between the base film layer 17 and the reflection pattern forming layer 18.

And at the interface, the incident light 61 is refracted in the direction shown to reach the first reflective surface 14. The first reflected light 62 reflected from the first reflective surface 14 is again incident on the second reflective surface 15, and the second reflected light 63 reflected from the second reflective surface 15 is emitted with high straightness to the light emitting surface 20. When the second reflected light is incident substantially perpendicular to the light emitting surface 20, an amount of light reflected from the interface between the air (the upper space of the second surface) and the second surface of the film member and back to the inside of the film member 11 again can be minimized, and thus the luminance can be greatly increased. That is, according to the present invention, even without using a prism sheet (typically, two sheets are stacked so that the prism shape is perpendicular) to increase the straightness of light by inducing refraction of light in order to conventionally increase a luminance, it is possible to ensure sufficient luminance.

The difference between the refractive index N1 of the base film layer 17 and the refractive index N2 of the reflective pattern shaping layer 18 is 0.69 or less, ie, N2−N1=0.69. If the refractive index difference N2−N1 of the two layers 17 and 18 exceeds 0.69, the refraction will be large, but rather exceed a range in which double reflections can occur well at the first reflective surface 14 and the second reflective surface 15. That is, the refracted light of the incident light 61 incident on the first reflective surface 14 becomes excessively large. In addition, when the difference between the two layers exceeds 0.69, the amount of reflection normally occurring at the interface of the two media increases and the amount of light passing through the interface of the two layers is drastically reduced.

Next, if the refractive index difference (N2−N1) of the two layers 17 and 18 is less than 0.05, the angle of refraction is not secured even if refraction occurs at the interface of the two layers. Thus when the second surface 20 and the first surface are parallel to each other and the light source 30 emits light horizontally as shown in FIG. 14, the double reflection is not smoothly performed.

FIG. 16 shows a reflective profile surface 13 in which a first reflective surface 14 is flat. As described above, the first reflective surface 14 serves to reflect the light incident from the light source to reach the second reflective surface 15, and Considering that intention of the present invention is to implement planar illumination, even if the reflective surface 14 is formed flat, there is no significant effect on the double reflection. However, comparing with the case that the first reflective surface 14 has a concave or convex curved surface, the second reflected light 63 reflected from the second reflective surface 15 tends to diffuse slightly, which only causes a slight decrease in brightness. Rather, when the first reflective surface 14 is flat, the reflective member 10 can be easily manufactured, and the manufacturing cost can be greatly reduced.

In contrast to FIG. 16, in FIG. 17, a structure in which the above-described connection portion 16 is formed between the double reflection patterns 14 and 15 that match each other is illustrated. A metal having high reflectivity may also be coated on the surface of the connection portion 16. Even if a metal or the like having high reflectivity is not coated on the connecting portion 16, when the incident light 61 irradiated from the light source 30 approaches the connecting portion 16, as shown in FIG. 17, it is reflected again (if there is metal coating) or total reflection (if there is no metal coating), it reaches the second surface 20 of the film member 11, and it is totally reflected again on the second surface and irradiated to the reflective profile surface at the lower portion of the film member, eventually double reflection occurs.

The connecting portion 16 can be used to adjust the distribution of the double reflection pattern to adjust the light distribution. For example, by reducing the length or frequency of the connecting portion 16 as the distance from the light source 30 increases difference between an amount of double reflection occurring close to the light source 30 and an amount of double reflection occurring far from the light source 30 can be minimized.

FIG. 18 illustrates that a film member 11 of which the first reflective surface 14 and the second reflective surface 15 have a concave structure can be applied. FIG. 19 illustrates that a film member 11 of which the first reflective surface 14 includes a convex shape and of which the second reflective surface 15 have a concave structure can be applied.

As in the fourth embodiment, if the film member itself has the function of guiding light, the planar illumination lighting device can be thin, such as a film, and the light emitting planar illuminating surface light can be flexibly deformed, thereby further expanding the utilization of the lighting.

According to the lighting apparatus, a convex profile also may be applied as the second reflective surface 15 since the diffusion of light is desired.

<Light Concentrating Device>

### First Embodiment

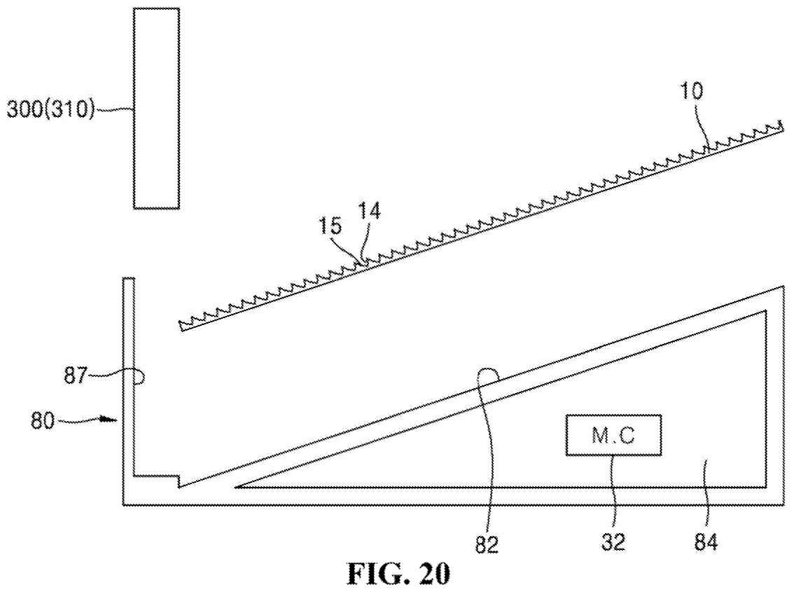

Referring now to FIGS. 20 to 22, a first embodiment of a photovoltaic module to which a light collecting apparatus according to the present invention is applied will be described.

The photovoltaic module comprises: a solar cell (310) for converting sunlight into electric energy; and a reflective member (10) for collecting sunlight and reflecting the sunlight to the solar cell (310). The solar cell 310 and the reflective member 10 are installed and assembled in the housing 80, thereby the relative positions of the solar cell 310 and the reflective member 10 can be fixed.

Solar cell 310 has an irradiation surface that absorbs sunlight. According to the present invention, the irradiation surface of the solar cell 310 is arranged side-by-side with respect to the incident direction of the sunlight. That is, the irradiation surface of the solar cell 310 does not directly face incident sunlight. Instead, the solar cell 310 is installed so that its irradiation surface faces the surface of the reflective member 10 for collecting and reflecting incident sunlight.

The housing 80 includes a solar cell installation part 87 in which the solar cell 310 is installed, and a reflective member mounting surface 82 on which the reflective member 10 is installed. A space having a cross section of a substantially right triangle shape provided on the rear surface of the reflective member installation surface 82 may be a receiving portion 84 provided with a substrate 32 for controlling the solar cell 310 and a direction changing module 89 to be described later.

The housing 80 may define an approximately rectangular parallelepiped space having a width of L and a depth of W.

A plurality of reflective profile surfaces 13 having a second reflective surface 15 and a first reflective surface 14 disposed adjacent to each other are arranged in parallel on the surface of the reflective member 10. The reflective profile surface 13 is repeatedly arranged in a direction away from the solar cell 310.

First, the reflective member 10 is inclined at a predetermined angle (a) with respect to the normal line of the solar radiation surface of the solar cell 310.

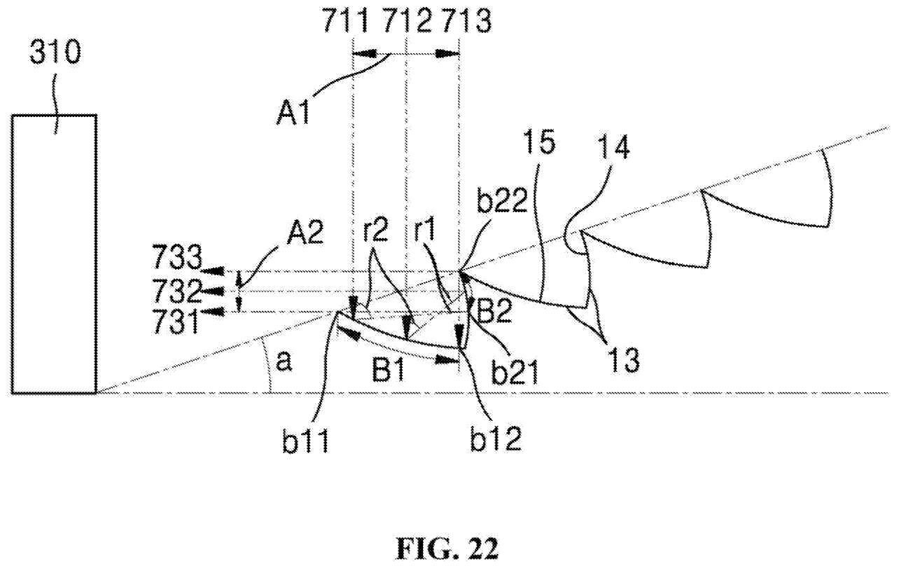

And, in the direction of incidence of sunlight (vertical direction in FIG. 22), the sunlight is parallel. In order to make concentrated reflection light parallel in the direction of incidence of the reflected light towards the irradiation surface of the solar cell 310 (in FIG. 22 in the left and right directions), the second reflective surface 15 and the first reflective surface 14 are formed so that only the second reflective surface 15 is exposed when viewed from the reflective member 10 in the incident direction of the sunlight, and only the first reflective surface 14 is exposed when viewed from the solar irradiation surface of the solar cell 310.

The second reflective surface 15 is arranged to reflect sunlight incident from the sun to the first reflective surface 14 adjacent thereto. The first reflective surface 14 is arranged to reflect sunlight reflected from the second reflective surface 15 to the solar radiation surface of the solar cell 310.

In this case, the area B2 of the first reflective surface 14 which the first reflected light reflected to the first reflective surface 14 from the area B 1 of the second reflective surface 15 on which the sunlight is incident reaches is an area exposed when the first reflective surface 14 is viewed from the solar radiation surface of the solar cell 310 as described above.

For example, if the reflection angle r2 of the primary reflection light is 89 degrees, the reflection angle r1 of the corresponding secondary reflection light is 1 degree (see 711 and 731 in FIG. 22), and the reflection angle r2 of the primary reflection light is if the angle is 45 degrees, the reflection angle r1 of the corresponding secondary reflection light is 45 degrees (see 712 and 732 in FIG. 22), and if the reflection angle r2 of the primary reflection light is 1 degree, the reflection angle of the corresponding secondary reflection light is The angle r1 is 89 degrees (see 713 and 733 in FIG. 3). In addition, the sum of the reflection angle r2 of the first reflected light reflected from the sunlight on the second reflective surface 15 and the reflection angle r1 of the second reflected light reflected from the first reflected light of the second reflective surface 15 on the first reflective surface 15 is set to be close to 90 degrees or 90 degrees. For example, if the reflection angle r2 of the first reflected light is 89°, the reflection angle r1 of the second reflected light corresponding to the reflection angle r2 is 1° (refer to 711 and 731 of FIG. 22), and if the reflection angle r2 of the first reflected light is 45°, the reflection angle r1 of the second reflected light corresponding to the reflection angle r2 is 45° (see 712 and 732 in FIG. 22), if the reflection angle r2 of the first reflected light is 1°, the reflection angle r1 of the second reflected light corresponding to the reflection angle r2 is 89° (see 713 and 733 in FIG. 3).

For example, in order to satisfy this rule, it is preferable that the second reflective surface has a profile so that the slope of the first point b11 of the region B1 of the second reflective surface 15 on which the sunlight is incident is −45° and the slope of the second point b12 is 0°, and in order to make the length of w relative to L very short, it is preferable that the second reflective surface has a concave profile.

And it is preferable that the first surface has a profile so that the slope of the first point b21 of the first reflective surface area B2 to which the first reflected light is incident is 90° and the slope of the second point b22 is −45°, and in order to make the length of w relative to L very short, the first reflective surface has a concave profile.

By having such a reflection angle and setting the profiles of the second reflective surface 15 and the first reflective surface 14, while concentrating light in a reflective manner, it occupies a small space and can be concentrated in the form of parallel light. While satisfying these conditions, if the inclination angle (a) of the reflective member 10 is formed to be small so that the distance L of the reflective member 10 extending from the solar irradiation surface of the solar cell 310 is longer than the width w of the solar irradiation surface of the solar cell 310, the solar power module can be made slim, and it is possible to concentrate light at a ratio of tangent a, and even if the solar power module is simply configured as above, solar power generation with concentrating light is possible.

That is, the relationship of tan a=A1/A2=w/L is satisfied.

According to the present invention, the light concentration rate of the sunlight is tangent a, the area of the solar cell can be reduced to the ratio of tangent a compared to the irradiation area of the sunlight, and the volume occupied by the photovoltaic power generation module is only as much as L*tan a as a thickness.

In addition, the space corresponding to the half of the thickness can be used as the accommodating part 84 of the housing 80, and it is possible to install various electric components such as the substrate 32 on the housing 80, thereby enabling the design of a compact and slim solar power generation module.

If the angle a is less than or equal to 45 degrees, the effect of the light concentration collection occurs, and even if the angle a is within 10 degrees, it is possible to collect light.

The reflective member 10 may be manufactured in the form of a film. The film can be manufactured by molding a synthetic resin film to have a surface profile of a pattern in which the reflective profile surfaces having the second reflective surface and the first reflective surface are repeated, and depositing aluminum on the surface. The film may be a UV curable resin.

When the reflective member 10 is manufactured in the form of a film, since making the reflective surface is done by only attaching the film to the reflective member mounting surface 82, the manufacturing cost can be greatly reduced.

Although a structure in which the solar cell 310 is installed as the concentrated light receiving portion 300 is illustrated in the embodiment of the present invention, a heat absorbing surface of a cooking utensil for boiling water may be disposed instead of the solar cell, if necessary.

Although not shown, a cylindrical lens may be installed just the front of the light-receiving surface of the concentrated light receiving portion 300 (the irradiation surface that absorbs sunlight of the solar cell), so that it is possible to concentrate light once more. The cylindrical lens can be arranged such that the central axis of the circle of the cylindrical lens is perpendicular to both the incident light 71 and the secondary reflection light 73.

### Second Embodiment

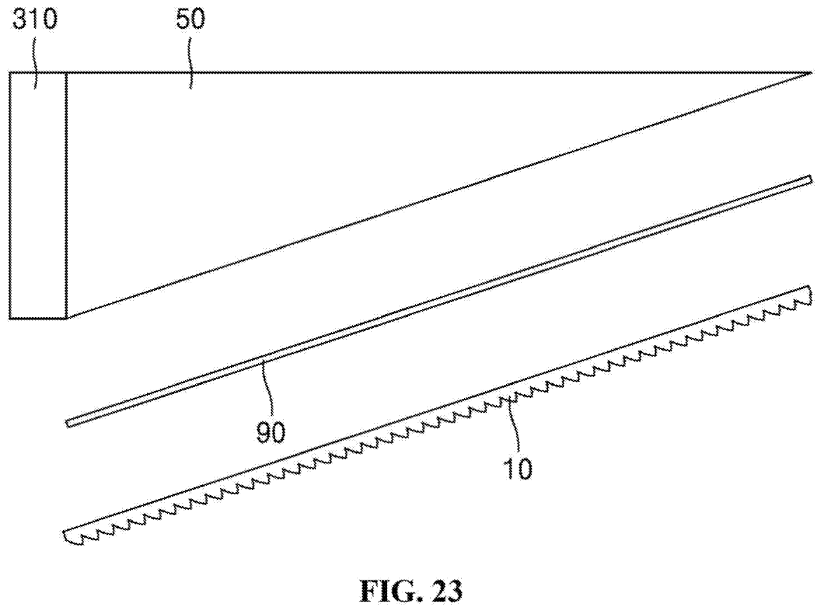

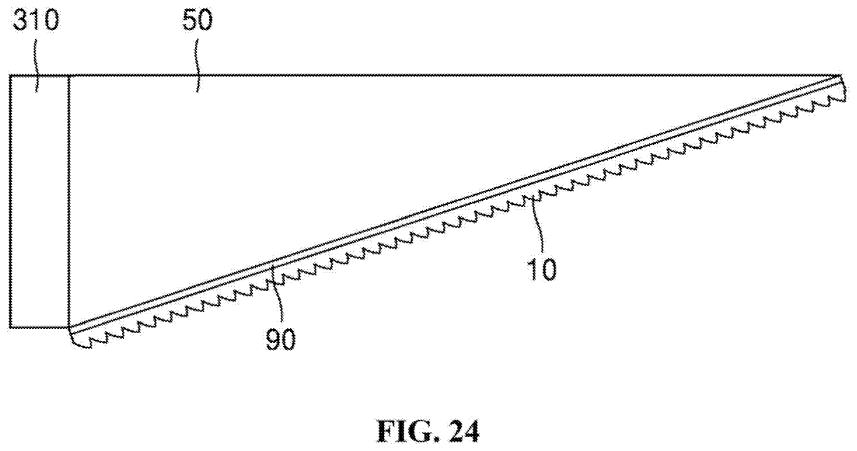

Referring now to FIGS. 23 to 25, a second embodiment of a photovoltaic module to which a light collecting apparatus according to the present invention is applied will be described. In the description of the second embodiment, the same description with the details of the first embodiment will be omitted.

In the second embodiment, the optical member 50 is further installed in a space where the reflective member 10 and the solar cell 310 face each other. The optical member 50 may be made of a material having a good light transmittance, such as acrylic, and is installed in a space between the surface of the solar irradiation surface and the surface of the reflective member 10. In addition, with respect to the incident angle of the sunlight, which is assumed to be incident on the reflective member 10, the incident surface of the optical member 50 has a planar surface that is perpendicular to the incident angle of the sunlight. The optical member 50 can be manufactured as a structure with a long right-angled triangular cross section.

A junction part of the optical member 50 and the reflective member 10 can be bonded by interposing an optical adhesive 90 having a similar density to the optical member and having a good light transmittance.

In addition, in the first embodiment, the sunlight reflection of the reflective member 10 is occurred on the back surface of the reflective member 10 rather than the front surface of the reflective member 10. As described in the first embodiment, the reflective member 10 may be manufactured in the form of a film. In the second embodiment, the film used for the reflective member 10 can be manufactured by forming a transparent synthetic resin film such as P.E. so that the film has a surface profile having a repeated pattern of the reflective profile surfaces on which the second reflective surface and the first reflective surface are formed, and depositing aluminum on the surface.

As described above, in the film forming the reflective member 10 of the second embodiment, the reflective surface becomes the back surface of the film. That is, the sunlight passes through the optical member 50, the optical adhesive 90, and the film member of the reflective member to reach the rear surface of the second reflective surface 15 of the reflective member.

Since aluminum is deposited on the surface of the synthetic resin film on which the reflective surface profile is formed on the surface of the reflective member, it should be noted that reflection can occur even if the light is irradiated on the rear surface of the reflective surface profile by passing the synthetic resin part of the film on the back side of the film as well as light is irradiated directly on the reflective surface profile from the outside of the film.

The sunlight reaching the rear surface of the second reflective surface 15 is reflected and is incident on the rear surface of the first reflective surface 14 through the synthetic resin portion of the film. The sunlight reflected from the back surface of the first reflective surface 14 is reflected as substantially parallel light, and is irradiated to the solar cell 310 through the synthetic resin portion of the film, the optical adhesive 90, and the optical member 50.

In order to minimize reflection and refraction from occurring at the interface between the film member and the optical adhesive, and at the interface between the optical adhesive and the optical member, the density of the film member and the optical adhesive and the optical member are preferably set to be similar to each other. That is, a material of each medium can be adopted to have a similar density to each other.

According to the second embodiment, since the solar cell 310 and the reflective member 10 can be fixed by the optical member 50, it is possible to omit the configuration of the housing 80 as illustrated in the first embodiment, or to manufacture the housing 80 in a different form.

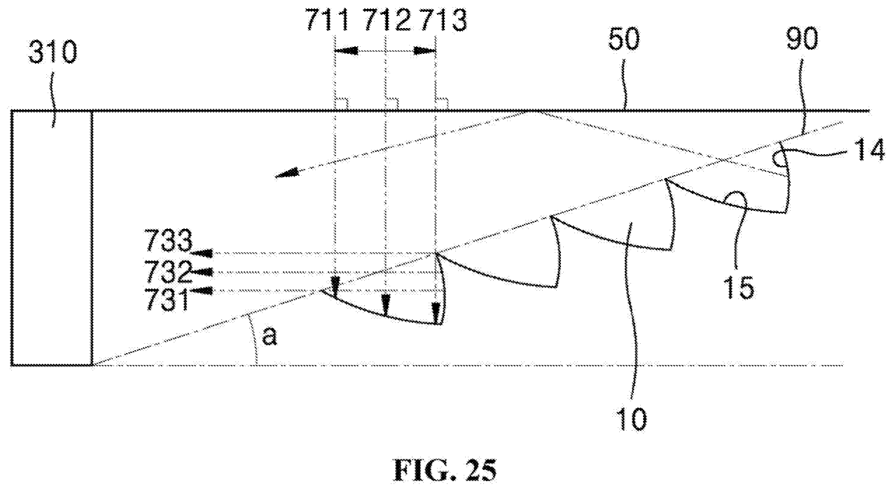

When the optical member 50 is further installed as in the second embodiment, the surface of the reflective member 10 of the photovoltaic module can be prevented from being contaminated. In addition, as shown in FIG. 25, the second reflective surface having a slight error in the first reflective surface 14 is reflected again from the incident surface of the optical member 50 and is incident to the irradiation surface of the solar cell 310.

### Third Embodiment

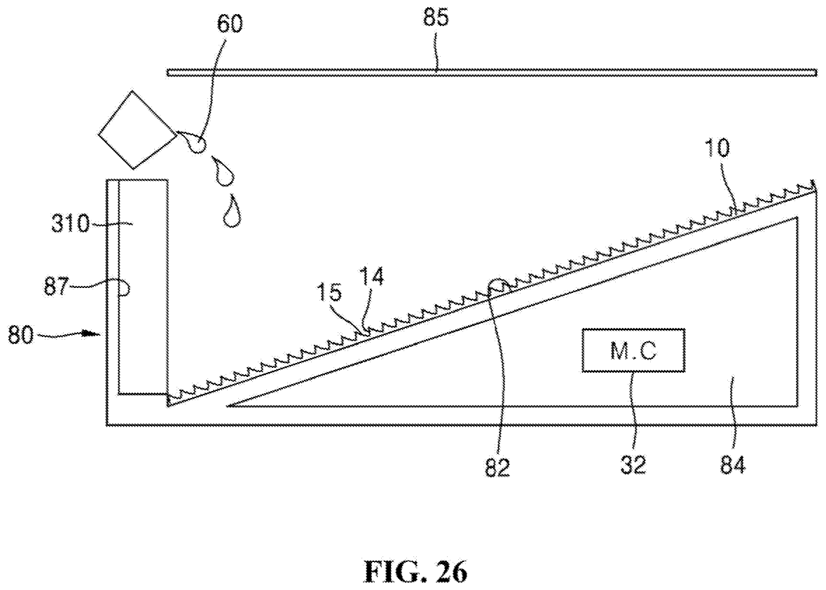

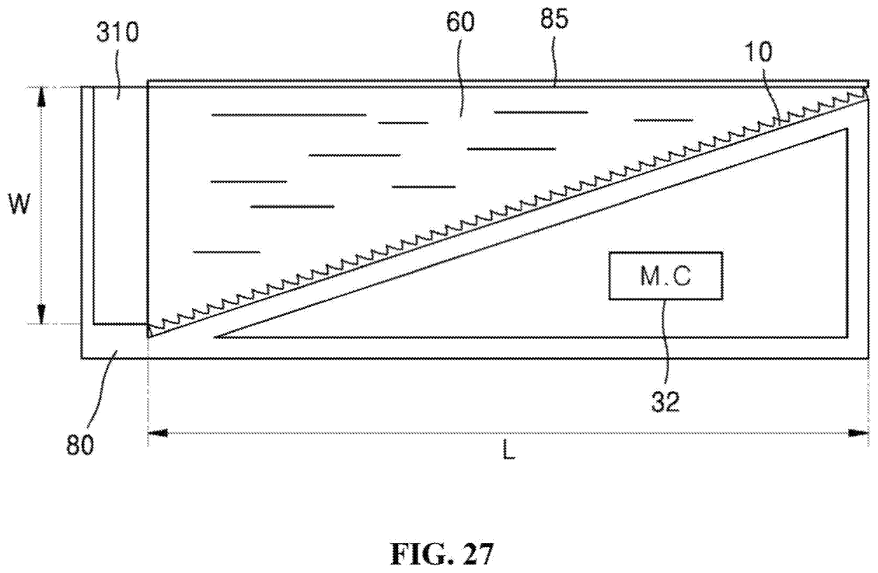

A third embodiment of the photovoltaic module according to the present invention will be described with reference to FIGS. 26 and 27. In the description of the third embodiment, the same description with the details of the first embodiment will be omitted.

The third embodiment is similar to the first embodiment, but differs from the first embodiment in that the optical structure similar to the optical member 50 of the second embodiment is implemented with the fluid medium 60 and the cover 85.

According to the third embodiment, after the reflective member 10 is installed in the housing 80, the fluid medium 70 is filled in the front space of the reflective member 10 and is sealed with a cover 85 so that the fluid medium 70 is not leaked. Then, the fluid medium 36 is filled into the space between the patterns of the first reflective surface 14 and the second reflective surface 15.

According to the third embodiment, the sunlight passes through the cover 85 and the fluid medium 60 to reach the surface of the second reflective surface 15 of the reflective member 10.

The sunlight reaching the surface of the second reflective surface 15 is reflected and incident on the back side of the first reflective surface 14 through the fluid medium 60. The sunlight reflected from the back surface of the first reflective surface 14 is reflected by substantially parallel light, and is irradiated to the solar cell 310 through the fluid medium 60.

According to the above structure, the surface of the reflective member 10 of the photovoltaic module can be prevented from being contaminated as in the second embodiment. In addition, the second reflected light, which is reflected on the first reflective surface 14 with a slight error, is totally reflected from the incident surface of the fluid medium 60 or the cover 85 to be incident to the irradiation surface of the solar cell 310.

In order to minimize reflection and refraction from occurring at the interface between the cover 85 and the fluid medium 70, the density of the cover and fluid medium is preferably set to be similar to each other. That is, a material of each medium can be adopted to have a similar density to each other.

### Fourth Embodiment

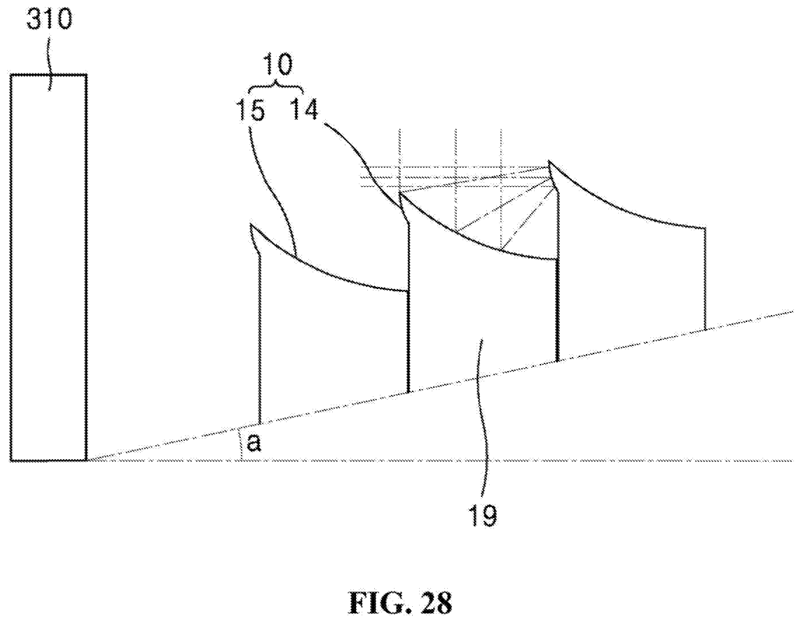

Referring now to FIG. 28, a fourth embodiment of a photovoltaic module according to the present invention is described. In describing the fourth embodiment, the same description with the details of the first embodiment will be omitted.

The fourth embodiment is different from the first embodiment in that the reflective member 10 is manufactured in a molded structure rather than a film structure, and the profile of the second reflective surface 15 and the first reflective surface 14 is different from the first embodiment.

In the fourth embodiment, the first reflective surface 14 is comprised of a convex profile. As a result of a research by the inventor, when the first reflective surface is convexly formed as shown in the fourth embodiment as compared to the concave first reflective surface as shown in the first embodiment, it is possible to construct the first reflective surface more compactly. In addition, compared with the first embodiment in which the first reflective surface is concave, if the first reflective surface has a convex profile, even if tracking the direction of direct sunlight is not accurate, the light reflected from the first reflective surface can reach the solar cell 310 more.

In the fourth embodiment, as in the first embodiment, the second reflective surface 15 is arranged to reflect sunlight incident from the sun into the first reflective surface 14 adjacent thereto, and the first reflective surface 14 is arranged to reflect the sunlight reflected from the second reflective surface 15 to the solar irradiation surface of the solar cell 310, and the angle relationship between the incident angle and the reflection angle is the same as that of the first embodiment. Thus the same detailed description thereof is omitted.

Next, in the fourth embodiment, unlike the first embodiment, the reflective member 10 is assembled with a plurality of identical unit patterns 19 which are fabricated respectively. One unit pattern 19 may include at least one second reflective surface 15 and a first reflective surface 14. In the fourth embodiment of the present invention, although one second reflective surface 15 and the first reflective surface form one unit pattern 19, the second reflective surface IS and the first reflective surface 14 which one unit pattern 19 has may be two or more.

As described above, the second reflective surface 15 and the first reflective surface 14 on which the same sunlight is reflected constitute one reflective profile surface 13, and the unit pattern 19 may include a second reflective surface 15 of one reflective profile surface 13 and a first reflective surface 14 of another reflective profile surface 13 adjacent to the one reflective profile surface.

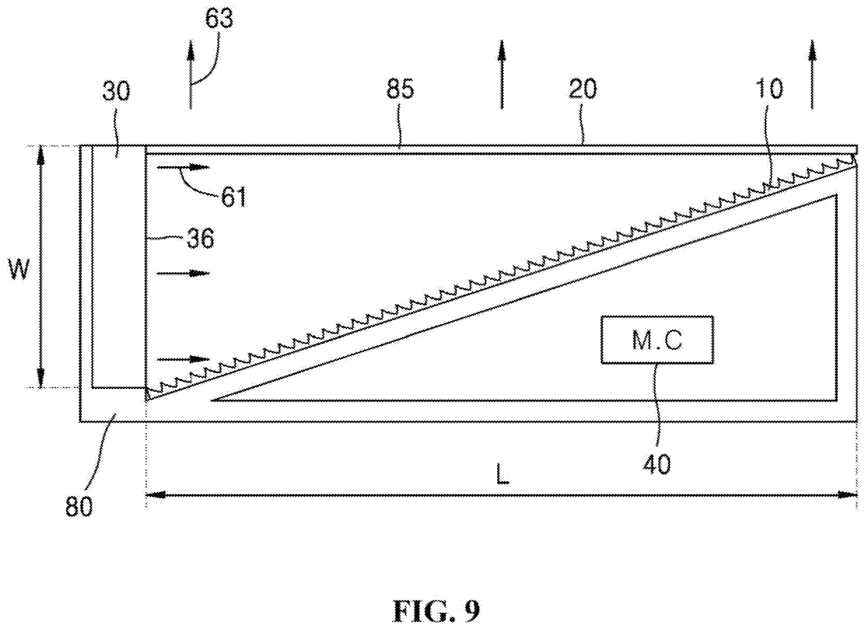

Then, as shown in FIG. 9, the shape of the unit pattern 19 can be simplified, and the unit pattern 19 can be manufactured in various ways. The simple unit pattern 19 shown in FIG. 9 can apply various molding processes such as injection molding, extrusion molding, etc. and the core mold is not required even when injection molding is performed.

The second reflective surface and the first reflective surface can be attached or deposited after forming the unit pattern.

### Fifth Embodiment

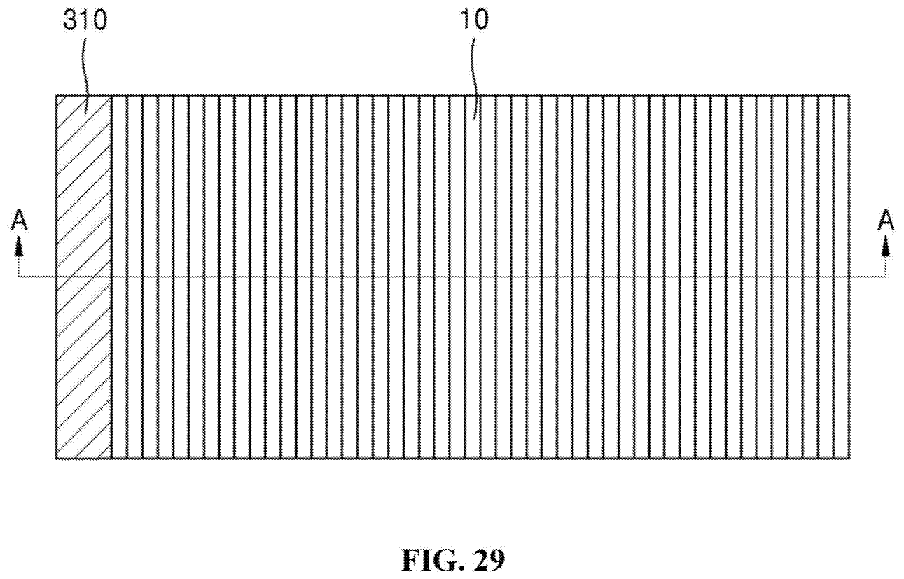

Hereinafter, a fifth embodiment of the photovoltaic module according to the present invention will be described with reference to FIG. 29.

As shown in FIG. 29, the plurality of reflective profile surfaces 13 can be arranged in parallel straight lines shape, and the reflective member 10 can be arranged in a planar shape on a side surface thereof.

According to the structure, since it is possible to manufacture the condensing photovoltaic module in a rectangular shape, it is possible to efficiently construct a plurality of power generation modules.

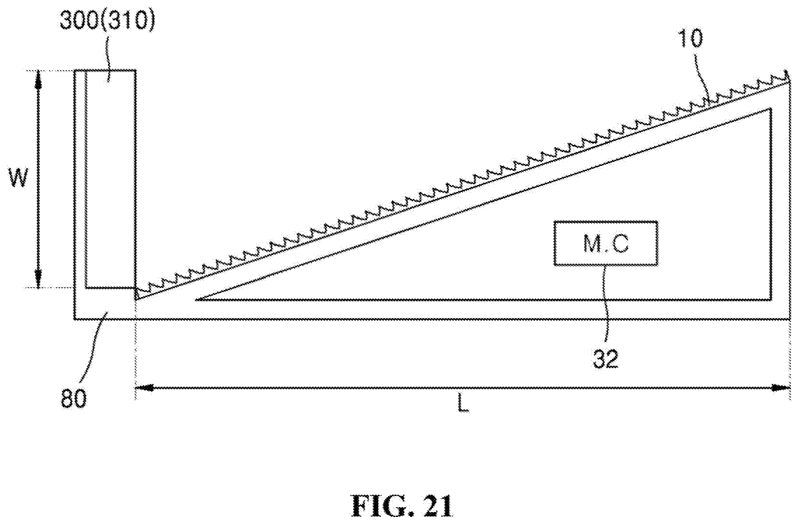

The A-A cross-section in FIG. 29 may be the first embodiment structure of FIG. 21, the second embodiment structure of FIG. 24, or the third embodiment structure of FIG. 27, or the fourth embodiment structure of FIG. 28.

### Sixth Embodiment

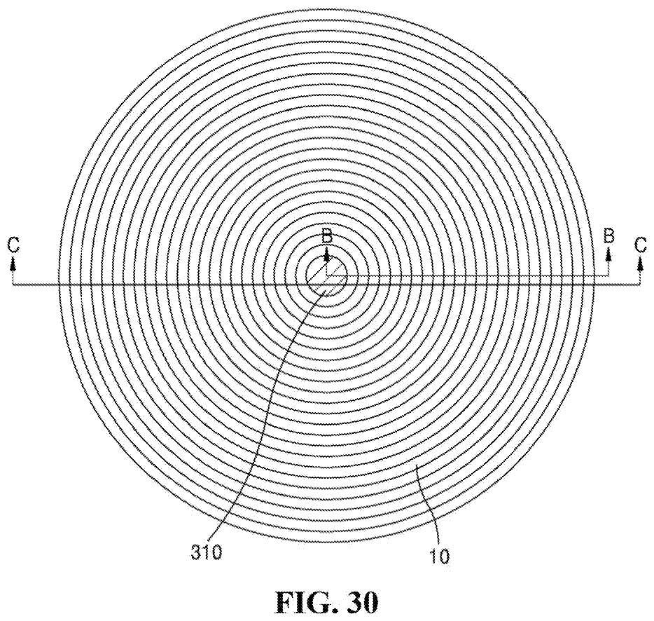

Hereinafter, a sixth embodiment of the photovoltaic module according to the present invention will be described with reference to FIG. 30.

As shown in FIG. 30, the plurality of reflective profile surfaces 13 May be arranged in concentric circles having a gradually increasing diameter, and the reflective member 10 may be arranged in a cylindrical shape at the center thereof.

Although not shown, it is possible to use the planar solar cell 310 by reflecting the collected light again by placing a cone-shaped mirror in the center, and installing a circular plate-shaped solar cell 310 on the vertex of the cone-shaped mirror.

According to the structure, the light concentration ratio of the condensing photovoltaic power generation module can be increased by a square number compared to the fifth embodiment, thereby maximizing light collection efficiency.

The B-B cross-section in FIG. 30 may be the first embodiment structure of FIG. 21, the second embodiment structure of FIG. 24, or the third embodiment structure of FIG. 27, or the fourth embodiment structure of FIG. 28.

### Seventh Embodiment

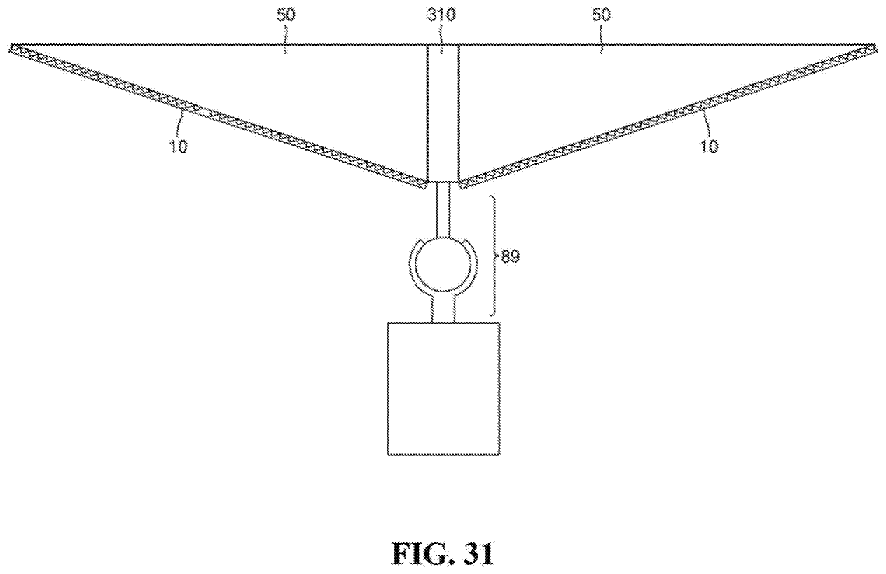

A seventh embodiment of a photovoltaic module according to the present invention will be described with reference to FIG. 31. In describing the seventh embodiment, the same details with the first to sixth embodiments will be omitted.

In the seventh embodiment, the solar power generation module disclosed in the fifth embodiment is an unit module, and the two or more solar power generation modules are arranged in two or more modules, thereby forming a single power generation module.

As shown in FIG. 31, the two unit power generation modules disclosed in FIG. 29 are installed to be symmetrical to each other, and a direction conversion module 89 is installed at a lower portion of the unit power generation modules, so that sunlight is vertically viewed by daylight hours.

Alternatively, it is possible to construct the large one photovoltaic module of the sixth embodiment as in the seventh embodiment. That is, the C-C cross-section of FIG. 30 is referred to as a portion of the photovoltaic module shown in FIG. 31, and a direction conversion module 89 is installed at a lower portion of the C-C section, so that sunlight is vertically viewed by daylight hours.

The connection type of the unit power generation module shown in FIG. 31 is merely an example, and in addition, the unit power generation module can be integrated with various rules.

As described above, even though the solar power generation module according to the present invention is not a precise tracker, sunlight can be properly collected and collected sunlight can be irradiated to the solar cell 310. Therefore, even if the direction conversion module 89 and the tracker are low-precision trackers, there is no problem in the light concentration development.

While the invention has been particularly shown and described with reference to exemplary embodiments thereof, it will be understood by those skilled in the art that various changes in form and details may be made therein without departing from the spirit and scope of the invention as defined by the appended claims. In addition, although the above-described embodiments of the present invention have been described above, it should be appreciated that the effects that can be predicted by the above-described configuration should also be considered.

1. A reflective member (10) which an incident light (61) in a first direction is incident to and then a diffused second reflected light (63) in a second direction different from the first direction is emitted, and an incident light (71) in the second direction is incident to and then a concentrated second reflected light (73) in the first direction is emitted, the reflective member (10) comprising:
a reflective profile surface (13) reflecting the incident light; and
first reflective surfaces (14) and second reflective surfaces (15) which are alternately provided on a surface of the reflective profile surface (13) along a longitudinal direction,
wherein, if the incident light (61) is incident in the first direction, it is incident on the first reflective surface (14), a first reflected light (62) reflected from the first reflective surface (14) is incident on the second reflective surface (15) which is adjacent to the first reflective surface (14) and is disposed closer to the incident direction of the incident light (61) than the first reflective surface (14), and the second reflected light (63) reflected from the second reflective surface (15) intersects the incident light (61) and is emitted in the second direction, and
wherein, if the incident light (71) is incident in the second direction, it is incident on the second reflective surface (15), a first reflected light (72) reflected from the second reflective surface (15) is incident on the first reflective surface (14) which is adjacent to the second reflective surface (15) and is disposed closer to the incident direction of the incident light (71) than the second reflective surface (15), and the second reflected light (73) reflected from the first reflective surface (14) intersects the incident light (71) and is emitted in the first direction.

2. The reflective member of claim 1, further comprising:
a film member (11) which includes a first surface having the reflective profile surface (13) and a second surface opposing to the first surface,
wherein the film member (11) is fabricated with flexible light-transmitting material,
wherein the film member includes a base film layer (17) having a predetermined thickness and a reflective pattern shaping layer (18) provided on a surface of the base film (17) and constituting the reflective profile surface (13), and
wherein a metal or a reflective ink is applied on the reflective profile surface (13) to form a first reflective surface (14) and a second reflective surface (15).

3. The reflective member of claim 1, further comprising:
connecting surfaces between the first reflective surfaces and the second reflective surfaces which are alternately arranged.

4. The reflective member of claim 1,
wherein the first reflective surface includes a convex or flat or concave surface profile when viewed from a direction in which light is incident, and the second reflective surface includes a concave curved surface when viewed from a direction in which light is incident.

5. A planar illuminating device comprising:
the reflective member (10) of claim 1, which is arranged at an angle (a) the same with or greater than 0 degree and less than 45 degrees with respect to a light emitting surface (20) which illuminates planarly; and
a light source (30) which emits light to the reflective member (10) between a light emitting surface and the reflective profile surface (13) of the reflective member (10),
wherein the incident light (61) emitted in the first direction from the light source (30) is incident on the first reflective surface (14), the first reflective light (62), to which the incident light (61) is reflected at the first reflective surface (14), is incident on the second reflective surface (15) which is adjacent to the first reflective surface (14) and is disposed closer to the light source (30) than the first reflective surface (14), and the second reflected light (63), to which the first reflective light (62) is reflected at the second reflective surface (15), intersects the incident light (61) and is emitted toward the light emitting surface (20).

6. The planar illuminating device of claim 5,
wherein the reflective member (10) further comprises a film member (11) which includes a first surface having the reflective profile surface (13) and a second surface opposing to the first surface, the incident light (61) is incident on the first reflective surface (14) toward the rear surface of the reflective profile surface (13) through the second surface of the film member (11) and the film member (11), the first reflected light (62) is incident on the second reflective surface (15) toward the opposite surface of the reflective profile surface (13) through the film member (11), and the second reflected light (63) is emitted to the light emitting surface (20) through the film member (1) and the second surface.

7. The planar illuminating device of claim 5,
wherein the reflective member further include a film member (11) which includes a first surface having the reflective profile surface (13) and a second surface opposing to the first surface, the film member (11) is fabricated with flexible light-transmitting material, the film member includes a base film layer (17) having a predetermined thickness and a reflective pattern shaping layer (18) provided on a surface of the base film (17) and constituting the reflective profile surface (13), and a metal or a reflective ink is applied on the reflective profile surface (13) to form a first reflective surface (14) and a second reflective surface (15),
wherein the reflective member (10) is disposed to face a light emitting surface (20) which illuminates planarly,
wherein the incident light (61) is incident into the film member (11) through the side surface of the film member (11), passes through the film member (10) toward the rear surface of the reflective profile surface (13) and is incident on the first reflective surface (14), the first reflected light (62) is incident on the second reflective surface (15) through the film member (11) toward the rear surface of the reflective profile surface (13), and the second reflected light (63) may be emitted through the second surface of the film member (11) to the light emitting surface (20), and
wherein a refractive index (N1) of the base film layer (17) and a refractive index (N2) of the reflective pattern shaping layer (18) satisfy a formula of 0.05≤N2−N1≤0.69.

8. A light collecting device comprising:
the reflective member (10) of claim 1; and
a concentrated light receiving portion (300) installed such that a sunlight irradiation surface of the concentrated light receiving portion faces a side of an incident direction of a sunlight with respect to the incident direction of the sunlight,
wherein the second reflective surface (15) is disposed to face the incident direction of the sunlight, the first reflective surface (14) is disposed to face the concentrated light receiving portion (300), the incident light (71) is incident on the second reflective surface (15) in the second direction, the first reflective light (72), to which the incident light (71) is reflected at the second reflective surface (15), is incident on the first reflective surface (14) adjacent to the second reflective surface (15), the second reflective light (73), to which the first reflective light (72) is reflected at the first reflective surface (14), intersects the incident light (71) and is emitted toward the concentrated light receiving portion (300).

9. The light concentrating device of claim 8,
wherein the reflective member (10) is arranged in a shape inclined at a predetermined angle (a) with respect to a normal line of the sunlight irradiation surface of the light collecting light receiving part (300), and the predetermined angle (a) is less than or equal to 45 degrees, and
wherein the reflective member (10) includes a structure in which the first reflective surface and the second reflective surface are arranged in a straight line shape in parallel or arranged in a concentric circle shape having different diameters.

10. The light concentrating device of claim 8,
wherein the sum of i) the reflection angle (r2) of the first reflected light (72) reflected from the second reflective surface (15) and ii) the reflection angle (r1) of the second reflected light (73) to which the first reflected light is reflected at the first reflective surface (14) is close to 90 degrees or 90 degrees.
